(19) United States
(12) Patent Application Publication
(10) Pub. No.: US 2023/0064193 A1
(43) Pub. Date: Mar. 2, 2023

(54) METROLOGY METHOD AND DEVICE FOR MEASURING A PERIODIC STRUCTURE ON A SUBSTRATE

(71) Applicant: ASML Netherlands B.V., Veldhoven (NL)

(72) Inventors: Patricius Aloysius Jacobus TINNEMANS, Hapert (NL); Patrick WARNAAR, Tilburg (NL); Vasco Tomas TENNER, Amsterdam (NL); Hugo Augustinus Joseph CRAMER, Eindhoven (NL); Bram Antonius Gerardus LOMANS, Eindhoven (NL); Bastiaan Lambertus Wilhelmus Marinus VAN DE VEN, Rosmalen (NL); Ahmet Burak CUNBUL, Eindhoven (NL); Alexander Prasetya KONIJNENBERG, Veldhoven (NL)

(73) Assignee: ASML Netherlands B.V., Veldhoven (NL)

(21) Appl. No.: 17/796,641

(22) PCT Filed: Jan. 20, 2021
(86) PCT No.: PCT/EP2021/051167

§ 371 Date: Jul. 29, 2022

(30) Foreign Application Priority Data
Jan. 29, 2020 (EP) 20154343.6
Mar. 6, 2020 (EP) 20161488.0
Jul. 21, 2020 (EP) 20186831.2

(51) Int. Cl. G06T 7/00; G01N 21/47; G03F 7/20; G06T 5/00

(52) U.S. Cl. CPC G06T 7/0006; G01N 21/4788; G03F 7/7065; G06T 5/006; G06T 2207/30148

(57) ABSTRACT

Disclosed is a method of measuring a periodic structure on a substrate with illumination radiation having at least one wavelength, the periodic structure having at least one pitch. The method comprises configuring, based on a ratio of said pitch and said wavelength, one or more of: an illumination aperture profile comprising one or more illumination regions in Fourier space; an orientation of the periodic structure for a measurement; and a detection aperture profile comprising one or more separated detection regions in Fourier space. This configuration is such that: i) diffracted radiation of at least a pair of complementary diffraction orders is captured within the detection aperture profile, and ii) said diffracted radiation fills at least 80% of the one or more separated detection regions. The periodic structure is measured while applying the configured one or more of illumination aperture profile, detection aperture profile and orientation of the periodic structure.

### CROSS REFERENCE TO RELATED APPLICATIONS

This application claims priority of EP application 20154343.6 which was filed on 2020-Jan.-29 and EP application 20161488.0 which was filed on 2020-Mar.-06 and EP application 20186831.2 which was filed on 2020-Jul.-21 and whom are incorporated herein in their entirety by reference.

### FIELD

The present invention relates to a metrology method and device for determining a characteristic of structures on a substrate.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) at a patterning device (e.g., a mask) onto a layer of radiation-sensitive material (resist) provided on a substrate (e.g., a wafer).

To project a pattern on a substrate a lithographic apparatus may use electromagnetic radiation. The wavelength of this radiation determines the minimum size of features which can be formed on the substrate. Typical wavelengths currently in use are 365 nm (i-line), 248 nm, 193 nm and 13.5 nm. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

Low-k₁ lithography may be used to process features with dimensions smaller than the classical resolution limit of a lithographic apparatus. In such process, the resolution formula may be expressed as CD=k₁×Δ/NA, where λ is the wavelength of radiation employed, NA is the numerical aperture of the projection optics in the lithographic apparatus, CD is the “critical dimension” (generally the smallest feature size printed, but in this case half-pitch) and k₁ is an empirical resolution factor. In general, the smaller k₁ the more difficult it becomes to reproduce the pattern on the substrate that resembles the shape and dimensions planned by a circuit designer in order to achieve particular electrical functionality and performance. To overcome these difficulties, sophisticated fine-tuning steps may be applied to the lithographic projection apparatus and/or design layout. These include, for example, but not limited to, optimization of NA, customized illumination schemes, use of phase shifting patterning devices, various optimization of the design layout such as optical proximity correction (OPC, sometimes also referred to as “optical and process correction”) in the design layout, or other methods generally defined as “resolution enhancement techniques” (RET). Alternatively, tight control loops for controlling a stability of the lithographic apparatus may be used to improve reproduction of the pattern at low k1.

In lithographic processes, it is desirable to make frequently measurements of the structures created, e.g., for process control and verification. Various tools for making such measurements are known, including scanning electron microscopes or various forms of metrology apparatuses, such as scatterometers. A general term to refer to such tools may be metrology apparatuses or inspection apparatuses.

A metrology device may apply computationally retrieved aberration corrections to an image captured by the metrology device. Descriptions of such metrology devices mention using coherent illumination and retrieving the phase of the field related to the image as a basis for the computational correction method. Coherent imaging has several challenges, and therefore it would be desirable to use (spatially) incoherent radiation in such a device

### SUMMARY

Embodiments of the invention are disclosed in the claims and in the detailed description.

In a first aspect of the invention there is provided a method of measuring a periodic structure on a substrate with illumination radiation having at least one wavelength, the periodic structure having at least one pitch, the method comprising: configuring, based on a ratio of said pitch and said wavelength, one or more of: an illumination aperture profile comprising one or more illumination regions in Fourier space; an orientation of the periodic structure for a measurement; and a detection aperture profile comprising one or more separated detection regions in Fourier space; such that: i) diffracted radiation of at least a pair of complementary diffraction orders is captured within the detection aperture profile, and ii) said diffracted radiation fills at least 80% of the one or more separated detection regions; and measuring the periodic structure while applying the configured one or more of illumination aperture profile, detection aperture profile and orientation of the periodic structure.

In a second aspect of the invention there is provided a metrology device for measuring a periodic structure on a substrate, the metrology device comprising: a detection aperture profile comprising one or more separated detection regions in Fourier space; and an illumination aperture profile comprising one or more illumination regions in Fourier space; wherein one or more of: said detection aperture profile, said illumination aperture profile and a substrate orientation of a substrate comprising a periodic structure being measured is/are configurable based on a ratio of at least one pitch of the periodic structure and at least one wavelength of illumination radiation used to measure said periodic structure, such that: i) at least a pair of complementary diffraction orders are captured within the detection aperture profile, and ii) radiation of the pair of complementary diffraction orders fills at least 80% of the one or more separated detection regions.

In another aspect of there is provided a metrology device for measuring a periodic structure on a substrate and having at least one periodic pitch, with illumination radiation having at least one wavelength, the metrology device comprising: an illumination aperture profile; and a configurable detection aperture profile and/or substrate orientation which is configurable for a measurement based on the illumination aperture profile and a ratio of said pitch and said wavelength such that at least a pair of complementary diffraction orders are captured within the detection aperture profile.

In another aspect there is provided a metrology device for measuring a periodic structure on a substrate and having at least one periodic pitch, with illumination radiation having at least one wavelength, the metrology device comprising: a substrate support for holding the substrate, the substrate support being rotatable around its optical axis, the metrology device being operable to optimize an illumination aperture profile by rotating the substrate around the optical axis in dependence on said ratio of pitch and wavelength.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus;

FIG. 2 depicts a schematic overview of a lithographic cell;

FIG. 3 depicts a schematic representation of holistic lithography, representing a cooperation between three key technologies to optimize semiconductor manufacturing;

FIG. 4 is a schematic illustration of a scatterometry apparatus;

FIG. 5 comprises (a) a schematic diagram of a dark field scatterometer for use in measuring targets according to embodiments of the invention using a first pair of illumination apertures, (b) a detail of diffraction spectrum of a target grating for a given direction of illumination (c) a second pair of illumination apertures providing further illumination modes in using the scatterometer for diffraction based overlay (DBO) measurements and (d) a third pair of illumination apertures combining the first and second pair of apertures;

FIG. 6 comprises a schematic diagram of a metrology device for use in measuring targets according to embodiments of the invention;

FIG. 7 illustrates (a) first illumination pupil and detection pupil profiles according to a first embodiment, (b) second illumination pupil and detection pupil profiles according to a second embodiment; and (c) third illumination pupil and detection pupil profiles according to a third embodiment.

FIG. 8 illustrates illumination pupil and detection pupil profiles for (a) an arrangement without wafer rotation; and (b) an arrangement with wafer rotation for six successive λ/P ratios according to embodiments of the invention;

FIG. 9 is a schematic illustration of an arrangement for obtaining an illumination profile with different illumination conditions for X-targets and Y-targets, according to an embodiment;

FIG. 10 (a)-(c) illustrates three proposed illumination arrangements for achieving such overfilled detection NA;

FIG. 11 illustrates an 8-part wedge concept to separately image each captured diffraction order;

FIG. 12 illustrates another embodiment of the 8-part wedge concept;

FIG. 13 illustrates a specific illumination NA and detection NA usable in embodiments of the invention;

FIG. 14 illustrates another specific illumination NA and detection NA usable in embodiments of the invention;

FIG. 15 is a schematic illustration of an arrangement for configuring both illumination and detection NA according to a first embodiment;

FIG. 16 is a schematic of an optical element which may be used in place of the optical wedges of FIG. 15;

FIG. 17 is a schematic of further optical elements which may be used in place of the optical wedges of FIG. 15;

FIG. 18 is a schematic illustration of an arrangement for configuring both illumination and detection NA according to a second embodiment;

FIG. 19 is a schematic illustration of an arrangement for configuring both illumination and detection NA according to a third embodiment; and

FIG. 20 depicts a block diagram of a computer system for controlling a system and/or method as disclosed herein.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

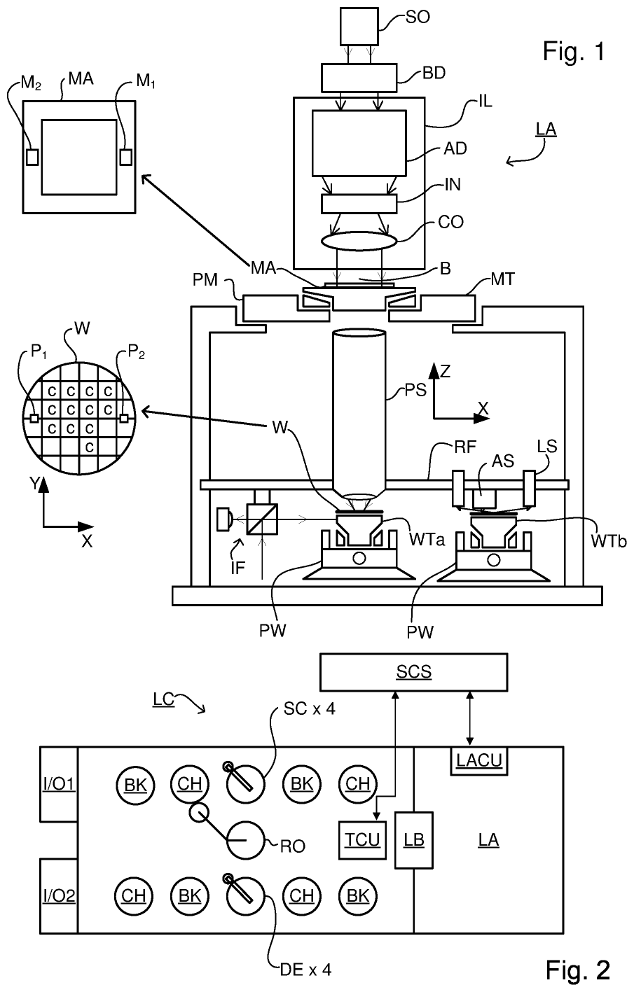

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W—which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

As shown in FIG. 2 the lithographic apparatus LA may form part of a lithographic cell LC, also sometimes referred to as a lithocell or (litho)cluster, which often also includes apparatus to perform pre- and post-exposure processes on a substrate W. Conventionally these include spin coaters SC to deposit resist layers, developers DE to develop exposed resist, chill plates CH and bake plates BK, e.g. for conditioning the temperature of substrates W e.g. for conditioning solvents in the resist layers. A substrate handler, or robot, RO picks up substrates W from input/output ports I/O1, I/O2, moves them between the different process apparatus and delivers the substrates W to the loading bay LB of the lithographic apparatus LA. The devices in the lithocell, which are often also collectively referred to as the track, are typically under the control of a track control unit TCU that in itself may be controlled by a supervisory control system SCS, which may also control the lithographic apparatus LA, e.g. via lithography control unit LACU.

In order for the substrates W exposed by the lithographic apparatus LA to be exposed correctly and consistently, it is desirable to inspect substrates to measure properties of patterned structures, such as overlay errors between subsequent layers, line thicknesses, critical dimensions (CD), etc. For this purpose, inspection tools (not shown) may be included in the lithocell LC. If errors are detected, adjustments, for example, may be made to exposures of subsequent substrates or to other processing steps that are to be performed on the substrates W, especially if the inspection is done before other substrates W of the same batch or lot are still to be exposed or processed.

An inspection apparatus, which may also be referred to as a metrology apparatus, is used to determine properties of the substrates W, and in particular, how properties of different substrates W vary or how properties associated with different layers of the same substrate W vary from layer to layer. The inspection apparatus may alternatively be constructed to identify defects on the substrate W and may, for example, be part of the lithocell LC, or may be integrated into the lithographic apparatus LA, or may even be a stand-alone device. The inspection apparatus may measure the properties on a latent image (image in a resist layer after the exposure), or on a semi-latent image (image in a resist layer after a post-exposure bake step PEB), or on a developed resist image (in which the exposed or unexposed parts of the resist have been removed), or even on an etched image (after a pattern transfer step such as etching).

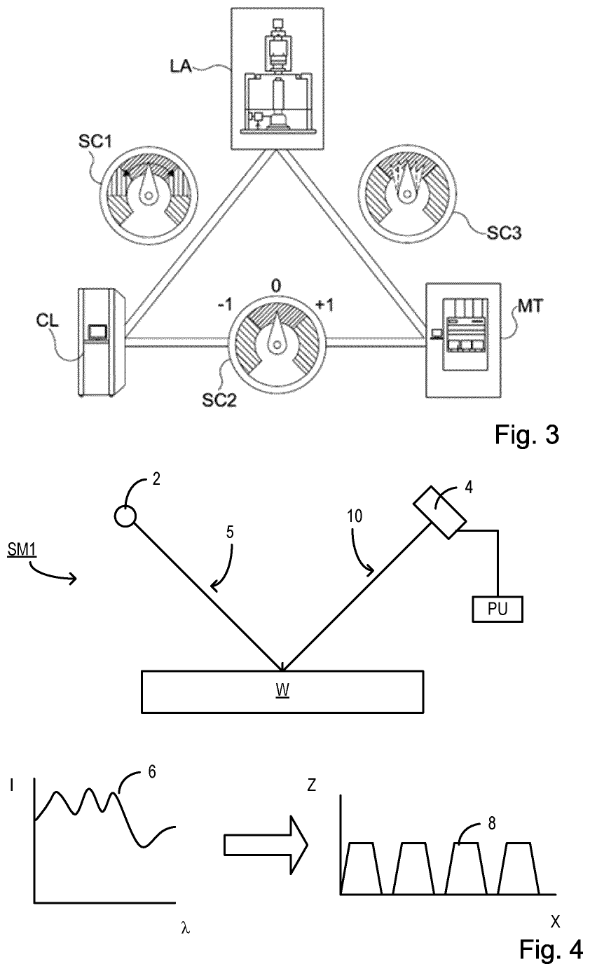

Typically the patterning process in a lithographic apparatus LA is one of the most critical steps in the processing which requires high accuracy of dimensioning and placement of structures on the substrate W. To ensure this high accuracy, three systems may be combined in a so called “holistic” control environment as schematically depicted in FIG. 3. One of these systems is the lithographic apparatus LA which is (virtually) connected to a metrology tool MET (a second system) and to a computer system CL (a third system). The key of such “holistic” environment is to optimize the cooperation between these three systems to enhance the overall process window and provide tight control loops to ensure that the patterning performed by the lithographic apparatus LA stays within a process window. The process window defines a range of process parameters (e.g. dose, focus, overlay) within which a specific manufacturing process yields a defined result (e.g. a functional semiconductor device)—typically within which the process parameters in the lithographic process or patterning process are allowed to vary.

The computer system CL may use (part of) the design layout to be patterned to predict which resolution enhancement techniques to use and to perform computational lithography simulations and calculations to determine which mask layout and lithographic apparatus settings achieve the largest overall process window of the patterning process (depicted in FIG. 3 by the double arrow in the first scale SC1). Typically, the resolution enhancement techniques are arranged to match the patterning possibilities of the lithographic apparatus LA. The computer system CL may also be used to detect where within the process window the lithographic apparatus LA is currently operating (e.g. using input from the metrology tool MET) to predict whether defects may be present due to e.g. sub-optimal processing (depicted in FIG. 3 by the arrow pointing “0” in the second scale SC2).

The metrology tool MET may provide input to the computer system CL to enable accurate simulations and predictions, and may provide feedback to the lithographic apparatus LA to identify possible drifts, e.g. in a calibration status of the lithographic apparatus LA (depicted in FIG. 3 by the multiple arrows in the third scale SC3).

In lithographic processes, it is desirable to make frequently measurements of the structures created, e.g., for process control and verification. Various tools for making such measurements are known, including scanning electron microscopes or various forms of metrology apparatuses, such as scatterometers. Examples of known scatterometers often rely on provision of dedicated metrology targets, such as underfilled targets (a target, in the form of a simple grating or overlapping gratings in different layers, that is large enough that a measurement beam generates a spot that is smaller than the grating) or overfilled targets (whereby the illumination spot partially or completely contains the target). Further, the use of metrology tools, for example an angular resolved scatterometer illuminating an underfilled target, such as a grating, allows the use of so-called reconstruction methods where the properties of the grating can be calculated by simulating interaction of scattered radiation with a mathematical model of the target structure and comparing the simulation results with those of a measurement. Parameters of the model are adjusted until the simulated interaction produces a diffraction pattern similar to that observed from the real target.

Scatterometers are versatile instruments which allow measurements of the parameters of a lithographic process by having a sensor in the pupil or a conjugate plane with the pupil of the objective of the scatterometer, measurements usually referred as pupil based measurements, or by having the sensor in the image plane or a plane conjugate with the image plane, in which case the measurements are usually referred as image or field based measurements. Such scatterometers and the associated measurement techniques are further described in patent applications US20100328655, US2011102753A1, US20120044470A, US20110249244, US20110026032 or EP1,628,164A, incorporated herein by reference in their entirety. Aforementioned scatterometers can measure in one image multiple targets from multiple gratings using light from soft x-ray and visible to near-IR wave range.

A metrology apparatus, such as a scatterometer, is depicted in FIG. 4. It comprises a broadband (white light) radiation projector 2 which projects radiation 5 onto a substrate W. The reflected or scattered radiation 10 is passed to a spectrometer detector 4, which measures a spectrum 6 (i.e. a measurement of intensity I as a function of wavelength of the specular reflected radiation 10. From this data, the structure or profile 8 giving rise to the detected spectrum may be reconstructed by processing unit PU, e.g. by Rigorous Coupled Wave Analysis and non-linear regression or by comparison with a library of simulated spectra. In general, for the reconstruction, the general form of the structure is known and some parameters are assumed from knowledge of the process by which the structure was made, leaving only a few parameters of the structure to be determined from the scatterometry data. Such a scatterometer may be configured as a normal-incidence scatterometer or an oblique-incidence scatterometer.

In a first embodiment, the scatterometer MT is an angular resolved scatterometer. In such a scatterometer reconstruction methods may be applied to the measured signal to reconstruct or calculate properties of the grating. Such reconstruction may, for example, result from simulating interaction of scattered radiation with a mathematical model of the target structure and comparing the simulation results with those of a measurement. Parameters of the mathematical model are adjusted until the simulated interaction produces a diffraction pattern similar to that observed from the real target.

In a second embodiment, the scatterometer MT is a spectroscopic scatterometer MT. In such spectroscopic scatterometer MT, the radiation emitted by a radiation source is directed onto the target and the reflected or scattered radiation from the target is directed to a spectrometer detector, which measures a spectrum (i.e. a measurement of intensity as a function of wavelength) of the specular reflected radiation. From this data, the structure or profile of the target giving rise to the detected spectrum may be reconstructed, e.g. by Rigorous Coupled Wave Analysis and non-linear regression or by comparison with a library of simulated spectra.

In a third embodiment, the scatterometer MT is an ellipsometric scatterometer. The ellipsometric scatterometer allows for determining parameters of a lithographic process by measuring scattered radiation for each polarization states. Such metrology apparatus emits polarized light (such as linear, circular, or elliptic) by using, for example, appropriate polarization filters in the illumination section of the metrology apparatus. A source suitable for the metrology apparatus may provide polarized radiation as well. Various embodiments of existing ellipsometric scatterometers are described in U.S. patent application Ser. No. 11/451,599, 11/708,678, 12/256,780, 12/486,449, 12/920,968, 12/922,587, 13/000,229, 13/033,135, 13/533,110 and 13/891,410 incorporated herein by reference in their entirety.

In one embodiment of the scatterometer MT, the scatterometer MT is adapted to measure the overlay of two misaligned gratings or periodic structures by measuring asymmetry in the reflected spectrum and/or the detection configuration, the asymmetry being related to the extent of the overlay. The two (typically overlapping) grating structures may be applied in two different layers (not necessarily consecutive layers), and may be formed substantially at the same position on the wafer. The scatterometer may have a symmetrical detection configuration as described e.g. in co-owned patent application EP1,628,164A, such that any asymmetry is clearly distinguishable. This provides a straightforward way to measure misalignment in gratings. Further examples for measuring overlay error between the two layers containing periodic structures as target is measured through asymmetry of the periodic structures may be found in PCT patent application publication no. WO 2011/012624 or US patent application US 20160161863, incorporated herein by reference in its entirety.

Other parameters of interest may be focus and dose. Focus and dose may be determined simultaneously by scatterometry (or alternatively by scanning electron microscopy) as described in US patent application US2011-0249244, incorporated herein by reference in its entirety. A single structure may be used which has a unique combination of critical dimension and sidewall angle measurements for each point in a focus energy matrix (FEM—also referred to as Focus Exposure Matrix). If these unique combinations of critical dimension and sidewall angle are available, the focus and dose values may be uniquely determined from these measurements.

A metrology target may be an ensemble of composite gratings, formed by a lithographic process, mostly in resist, but also after etch process for example. Typically the pitch and line-width of the structures in the gratings strongly depend on the measurement optics (in particular the NA of the optics) to be able to capture diffraction orders coming from the metrology targets. As indicated earlier, the diffracted signal may be used to determine shifts between two layers (also referred to ‘overlay’) or may be used to reconstruct at least part of the original grating as produced by the lithographic process. This reconstruction may be used to provide guidance of the quality of the lithographic process and may be used to control at least part of the lithographic process. Targets may have smaller sub-segmentation which are configured to mimic dimensions of the functional part of the design layout in a target. Due to this sub-segmentation, the targets will behave more similar to the functional part of the design layout such that the overall process parameter measurements resembles the functional part of the design layout better. The targets may be measured in an underfilled mode or in an overfilled mode. In the underfilled mode, the measurement beam generates a spot that is smaller than the overall target. In the overfilled mode, the measurement beam generates a spot that is larger than the overall target. In such overfilled mode, it may also be possible to measure different targets simultaneously, thus determining different processing parameters at the same time.

Overall measurement quality of a lithographic parameter using a specific target is at least partially determined by the measurement recipe used to measure this lithographic parameter. The term “substrate measurement recipe” may include one or more parameters of the measurement itself, one or more parameters of the one or more patterns measured, or both. For example, if the measurement used in a substrate measurement recipe is a diffraction-based optical measurement, one or more of the parameters of the measurement may include the wavelength of the radiation, the polarization of the radiation, the incident angle of radiation relative to the substrate, the orientation of radiation relative to a pattern on the substrate, etc. One of the criteria to select a measurement recipe may, for example, be a sensitivity of one of the measurement parameters to processing variations. More examples are described in US patent application US2016-0161863 and published US patent application US 2016/0370717A1 incorporated herein by reference in its entirety.

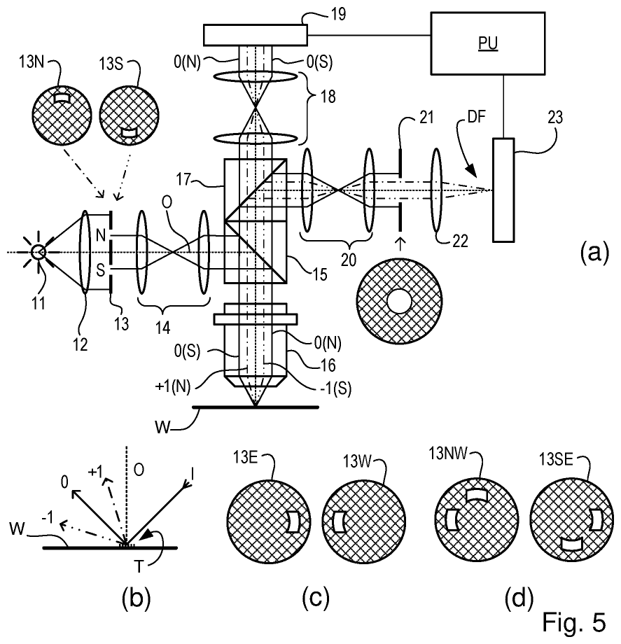

FIG. 5(a) presents an embodiment of a metrology apparatus and, more specifically, a dark field scatterometer. A target T and diffracted rays of measurement radiation used to illuminate the target are illustrated in more detail in FIG. 5(b). The metrology apparatus illustrated is of a type known as a dark field metrology apparatus. The metrology apparatus may be a stand-alone device or incorporated in either the lithographic apparatus LA, e.g., at the measurement station, or the lithographic cell LC. An optical axis, which has several branches throughout the apparatus, is represented by a dotted line O. In this apparatus, light emitted by source 11 (e.g., a xenon lamp) is directed onto substrate W via a beam splitter 15 by an optical system comprising lenses 12, 14 and objective lens 16. These lenses are arranged in a double sequence of a 4F arrangement. A different lens arrangement can be used, provided that it still provides a substrate image onto a detector, and simultaneously allows for access of an intermediate pupil-plane for spatial-frequency filtering. Therefore, the angular range at which the radiation is incident on the substrate can be selected by defining a spatial intensity distribution in a plane that presents the spatial spectrum of the substrate plane, here referred to as a (conjugate) pupil plane. In particular, this can be done by inserting an aperture plate 13 of suitable form between lenses 12 and 14, in a plane which is a back-projected image of the objective lens pupil plane. In the example illustrated, aperture plate 13 has different forms, labeled 13N and 13S, allowing different illumination modes to be selected. The illumination system in the present examples forms an off-axis illumination mode. In the first illumination mode, aperture plate 13N provides off-axis from a direction designated, for the sake of description only, as ‘north’. In a second illumination mode, aperture plate 13S is used to provide similar illumination, but from an opposite direction, labeled ‘south’. Other modes of illumination are possible by using different apertures. The rest of the pupil plane is desirably dark as any unnecessary light outside the desired illumination mode will interfere with the desired measurement signals.

As shown in FIG. 5(b), target T is placed with substrate W normal to the optical axis O of objective lens 16. The substrate W may be supported by a support (not shown). A ray of measurement radiation I impinging on target T from an angle off the axis O gives rise to a zeroth order ray (solid line 0) and two first order rays (dot-chain line +1 and double dot-chain line −1). It should be remembered that with an overfilled small target, these rays are just one of many parallel rays covering the area of the substrate including metrology target T and other features. Since the aperture in plate 13 has a finite width (necessary to admit a useful quantity of light, the incident rays I will in fact occupy a range of angles, and the diffracted rays 0 and +1/−1 will be spread out somewhat. According to the point spread function of a small target, each order +1 and −1 will be further spread over a range of angles, not a single ideal ray as shown. Note that the grating pitches of the targets and the illumination angles can be designed or adjusted so that the first order rays entering the objective lens are closely aligned with the central optical axis. The rays illustrated in FIGS. 5(a) and 3(b) are shown somewhat off axis, purely to enable them to be more easily distinguished in the diagram.

At least one of the first orders diffracted by the target T on substrate W are collected by objective lens 16 and directed back through beam splitter 15. Returning to FIG. 5(a), both the first and second illumination modes are illustrated, by designating diametrically opposite apertures labeled as north (N) and south (S). When the incident ray I of measurement radiation is from the north side of the optical axis, that is when the first illumination mode is applied using aperture plate 13N, the +1 diffracted rays, which are labeled +1(N), enter the objective lens 16. In contrast, when the second illumination mode is applied using aperture plate 13S the −1 diffracted rays (labeled 1(S)) are the ones which enter the lens 16.

A second beam splitter 17 divides the diffracted beams into two measurement branches. In a first measurement branch, optical system 18 forms a diffraction spectrum (pupil plane image) of the target on first sensor 19 (e.g. a CCD or CMOS sensor) using the zeroth and first order diffractive beams Each diffraction order hits a different point on the sensor, so that image processing can compare and contrast orders. The pupil plane image captured by sensor 19 can be used for focusing the metrology apparatus and/or normalizing intensity measurements of the first order beam. The pupil plane image can also be used for many measurement purposes such as reconstruction.

In the second measurement branch, optical system 20, 22 forms an image of the target T on sensor 23 (e.g. a CCD or CMOS sensor). In the second measurement branch, an aperture stop 21 is provided in a plane that is conjugate to the pupil-plane. Aperture stop 21 functions to block the zeroth order diffracted beam so that the image of the target formed on sensor 23 is formed only from the −1 or +1 first order beam. The images captured by sensors 19 and 23 are output to processor PU which processes the image, the function of which will depend on the particular type of measurements being performed. Note that the term ‘image’ is used here in a broad sense. An image of the grating lines as such will not be formed, if only one of the −1 and +1 orders is present.

The particular forms of aperture plate 13 and field stop 21 shown in FIG. 5 are purely examples. In another embodiment of the invention, on-axis illumination of the targets is used and an aperture stop with an off-axis aperture is used to pass substantially only one first order of diffracted light to the sensor. In yet other embodiments, 2nd, 3rd and higher order beams (not shown in FIG. 5) can be used in measurements, instead of or in addition to the first order beams.

In order to make the measurement radiation adaptable to these different types of measurement, the aperture plate 13 may comprise a number of aperture patterns formed around a disc, which rotates to bring a desired pattern into place. Note that aperture plate 13N or 13S can only be used to measure gratings oriented in one direction (X or Y depending on the set-up). For measurement of an orthogonal grating, rotation of the target through 90° and 270° might be implemented. Different aperture plates are shown in FIGS. 5(c) and (d). The use of these, and numerous other variations and applications of the apparatus are described in prior published applications, mentioned above.

The metrology tool just described requires low aberrations (for good machine-to-machine matching for example) and a large wavelength range (to support a large application range for example). Machine-to-machine matching depends (at least partly) on aberration variation of the (microscope) objective lenses being sufficiently small, a requirement that is challenging and not always met. This also implies that it is essentially not possible to enlarge the wavelength range without worsening the optical aberrations. Furthermore, the cost of goods, the volume and/or the mass of a tool is substantial, limiting the possibility of increasing the wafer sampling density (more points per wafer, more wafers per lot) by means of parallelization by providing multiple sensors to measure the same wafer simultaneously.

To address at least some of these issues, a metrology apparatus which employs a computational imaging/phase retrieval approach has been described in US patent publication US2019/0107781, which is incorporated herein by reference. Such a metrology device may use relatively simple sensor optics with unexceptional or even relatively mediocre aberration performance. As such, the sensor optics may be allowed to have aberrations, and therefore produce a relatively aberrated image. Of course, simply allowing larger aberrations within the sensor optics will have an unacceptable impact on the image quality unless something is done to compensate for the effect of these optical aberrations. Therefore, computational imaging techniques are used to compensate for the negative effect of relaxation on aberration performance within the sensor optics.

In such an approach, the intensity and phase of the target is retrieved from one or multiple intensity measurements of the target. The phase retrieval may use prior information of the metrology target (e.g., for inclusion in a loss function that forms the starting point to derive/design the phase retrieval algorithm). Alternatively, or in combination with the prior information approach, diversity measurements may be made. To achieve diversity, the imaging system is slightly altered between the measurements. An example of a diversity measurement is through-focus stepping, i.e., by obtaining measurements at different focus positions. Alternative methods for introducing diversity include, for example, using different illumination wavelengths or a different wavelength range, modulating the illumination, or changing the angle of incidence of the illumination on the target between measurements. The phase retrieval itself may be based on that described in the aforementioned US2019/0107781, or in patent application EP3480554 (also incorporated herein by reference). This describes determining from an intensity measurement, a corresponding phase retrieval such that interaction of the target and the illumination radiation is described in terms of its electric field or complex-valued field (“complex” here meaning that both amplitude and phase information is present). The intensity measurement may be of lower quality than that used in conventional metrology, and therefore may be out-of-focus as described. The described interaction may comprise a representation of the electric and/or magnetic field immediately above the target. In such an embodiment, the illuminated target electric and/or magnetic field image is modelled as an equivalent source description by means of infinitesimal electric and/or magnetic current dipoles on a (e.g., two-dimensional) surface in a plane parallel with the target. Such a plane may, for example be a plane immediately above the target, e.g., a plane which is in focus according to the Rayleigh criterion, although the location of the model plane is not critical: once amplitude and phase at one plane are known, they can be computationally propagated to any other plane (in focus, out of focus, or even the pupil plane). Alternatively, the description may comprise a complex transmission of the target or a two-dimensional equivalent thereof.

The phase retrieval may comprise modeling the effect of interaction between the illumination radiation and the target on the diffracted radiation to obtain a modelled intensity pattern; and optimizing the phase and amplitude of the electric field/complex-valued field within the model so as to minimize the difference between the modelled intensity pattern and the detected intensity pattern. More specifically, during a measurement acquisition, an image (e.g., of a target) is captured on detector (at a detection plane) and its intensity measured. A phase retrieval algorithm is used to determine the amplitude and phase of the electric field at a plane for example parallel with the target (e.g., immediately above the target). The phase retrieval algorithm uses a forward model of the sensor (e.g. aberrations are taken into account), to computationally image the target to obtain modelled values for intensity and phase of the field at the detection plane. No target model is required. The difference between the modelled intensity values and detected intensity values is minimized in terms of phase and amplitude (e.g., iteratively) and the resultant corresponding modelled phase value is deemed to be the retrieved phase. Specific methods for using the complex-valued field in metrology applications are described in PCT application PCT/EP2019/052658, also incorporated herein by reference.

However the illuminated computational imaging based metrology sensor such as described in the aforementioned publications is (mainly) designed for use with spatially coherent, or partially spatially coherent radiation. This results in the following drawbacks:
The optical crosstalk performance is severely impacted by the fact that the (partial) coherent point spread function is substantial larger than the (near) incoherent point spread function. This limits the process variation performance due to the impact of variations in neighboring customer structures on the measured intensity asymmetry of the metrology target (e.g., from which overlay or focus is inferred). Also of note is that for a given identical detection NA, the incoherent resolution (limit) is twice as good as the coherent resolution (limit), which is (from a different but related viewpoint) also beneficial to reduce optical crosstalk.
An (iterative) phase retrieval is required which requires a substantial amount of computational hardware, which increases the overall cost of goods of the metrology sensor. Also the phase retrieval is based on multiple diversity measurements, to provide the necessary information needed to retrieve the phase. It is estimated that practically speaking 2 to 10 diversity measurements are needed, increasing sensor acquisition time and/or complexity. For example, the diversity may be obtained by performing measurements sequentially at multiple focus levels. Obtaining stepwise defocused images is therefore slow, resulting in a slow measurement speed and low throughput. A simple calculation demonstrates this. Assuming that 5 through-focus images are taken for each combination of 4 (angular) directions and 5 (sequentially captured) wavelengths, and each image takes 1 ms to capture, it will take about 100 ms to measure each target. This does not include the time taken for moving the stages and switching wavelengths. In addition, the phase retrieval calculation (which is typically iterative) itself can be computationally intensive and take a long time to converge to a solution.
Because, for a coherent illuminated computational imaging based metrology sensor, the detection NA (numerical aperture) is larger than the illumination NA, it is required to have a switchable illuminator which allows sequential measurement of the +1st and −1st diffraction orders for an x-target and y-target (hence the ability to switch between four illumination modes). In particular, darkfield imaging requires this, as the images of the +1st and −1st diffraction order can end up being located on top of one another for specific λ/P ratios. The alternative (which would not require a switchable illuminator) of having one (low NA) coherent illuminator and four (large NA) detection pupils, does not fit in the available k-space/pupil space/Fourier space/solid angular space (the terms can be used synonymously) for the desired range of λ/P ratios. This increases the complexity, volume and cost of goods of the illumination, which is a disadvantage if one wants to parallelize multiple sensors to increase wafer sampling density. An additional drawback of this sequential measurement of the +1st and −1st diffraction orders, is that the sensor is not insensitive for (spatial average) temporal dose variations of the illumination source.

To address these issues, it is proposed to use a spatial incoherent or a close approximation (or at least multimode) illuminated computational imaging based metrology sensor. Such a metrology sensor may be a darkfield metrology sensor, e.g., for the measurement of asymmetry and parameters derived therefrom such as overlay and focus. For the remaining description, the term incoherent illumination will be used to describe spatially incoherent illumination or a close approximation thereof.

There are two conditions/assumptions under which monochromatic image formation may be assumed to be spatially incoherent; these two conditions/assumptions are:

$$\overline{O} ( {k}_{x}^{′} , {k}_{y}^{′} , {k}_{x} , {k}_{y} ) = \overline{O} ( {k}_{x}^{′} - {k}_{x} , {k}_{y}^{′} - {k}_{y} )$$

$${lim}_{𝒦 \to {ℝ}^{2}} {\int \int }_{𝒦} exp ( i {\frac{2 π}{λ} [ \begin{matrix}{k}_{x} \\ {k}_{y}\end{matrix} ]}^{T} \cdot [ \begin{matrix}{x}^{′} - {x}^{″} \\ {y}^{′} - {y}^{″}\end{matrix} ] ) {dk}_{x} , {dk}_{y} = δ ( {x}^{′} - {x}^{″} , {y}^{′} - {y}^{″} )$$

where kₓ, k_{y} are the x and y parameters in pupil space (k space), Ō(kₓ, k_{y}) denotes the angular spectrum representation of the object (scalar) electric field function O(x, y), λ is the wavelength, [symbol] dkₓ, dk_{y} denotes the integration over the Kohler type illumination pupil [symbol] and δ denotes the Dirac delta function. Note that in practice the illumination spatial coherence length (for example expressed near the target or near the detector) will be larger than zero, i.e. the illuminator is not of the ideal Kohler type, but the above assumptions are still valid/made in that case also, to result in a computational model of the (near) spatial incoherent image formation. Note in case of non-monochromatic illumination, an extension of this incoherent imaging formalism is possible under a third assumption, which is that the target response does not (significantly) depend on the wavelength.

To aid implementation of spatially incoherent illumination, while suppressing the optical cross talk from structures (with different periodic pitches) near the overlay and/or focus target (for example), an optimized illumination arrangement is proposed in which the position of the illumination pupil is chosen dependent on a λ/P ratio of the illumination wavelength λ (where λ equals the central wavelength for example in case of an illumination bandwidth which is not small) and target pitch P, so as to ensure a pair of complementary higher diffraction orders (e.g., the +1 order and −1 order) coincide in pupil space (k-space) with the (e.g., fixed) detection aperture profile. In an embodiment, the illumination NA is set to be equal or (e.g., slightly) larger than the detection NA. Slightly larger may be up to 5% larger, up to 10% larger, up to 15% larger or up to 20% larger, for example. In an optional embodiment the pupil space may be shared by two pairs of diffraction orders (and therefore two incident illumination angular directions), one per direction to enable simultaneous detection in X and Y. Note that, while the teachings herein have particular applicability to incoherent systems (due to the larger illumination NA of such systems), it is not so limited and the concepts disclosed herein are applicable to coherent and partially or near coherent systems.

Maintaining the detection aperture profile fixed may simplify the optical design. However, an alternative implementation may comprise fixing the illumination aperture profile and configuring the detection aperture profile according to the same requirements. In addition both illumination and detection aperture profiles may be configurable to adapt both illumination and detection pupil location, so as to maintain the diffraction orders coincident with the location of the detection pupil.

A pair of complementary diffraction orders in the context of this disclosure may comprise, for example, any higher (i.e., non-zeroth) order pair of diffraction orders of the same order (e.g., the +1 order and −1 order). The pair of complementary diffraction orders may originate from two separate illuminations from substantially different directions (e.g., opposing directions), e.g., a −1 diffraction order from illumination from a first illumination direction and a +1 diffraction order from illumination from a second illumination direction. Alternatively, the pair of complementary diffraction orders may originate from a single illumination beam, such that the configuring of an illumination aperture profile and/or orientation of the periodic structure according to a detection aperture profile and wavelength/pitch combination captures both the −1 and +1 diffraction orders resultant from this single illumination beam.

An additional benefit of using spatial incoherent illumination (or close approximation), is it enables the possibility of using an extended source, e.g., with a finite bandwidth; the use of a laser like source is not mandatory, as it practically speaking would be for a spatial coherent illumination.

Simultaneously measuring both the +1st and −1st diffraction orders for either (or both) of the X-target or Y-target has the benefit that the impact of intensity noise and wavelength noise (e.g. mode hopping) is easier to suppress, and highly likely to be better suppressed.

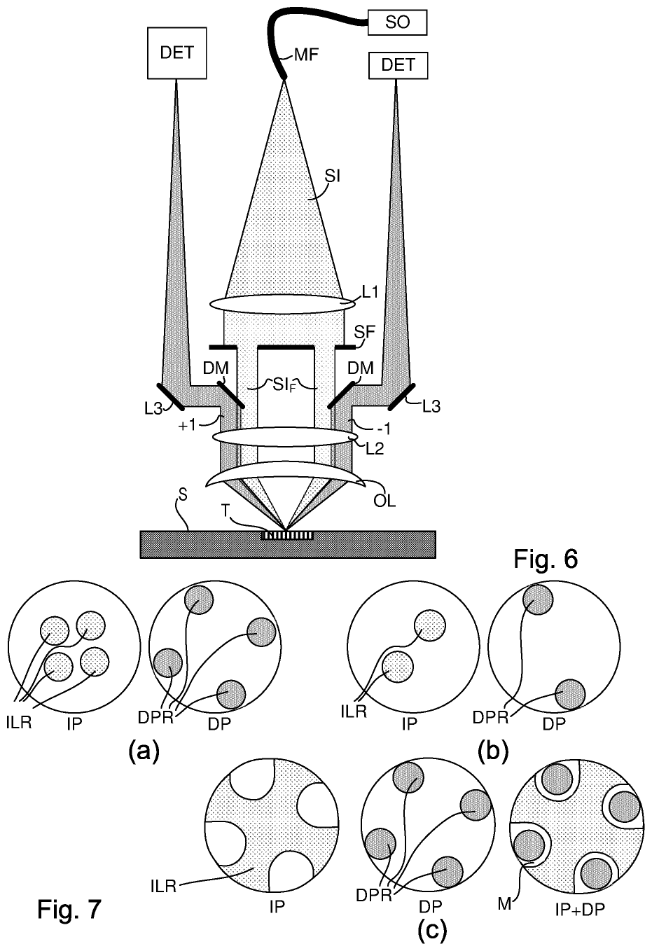

FIG. 6 is a schematic illustration of such a metrology tool according to an embodiment. Note that this is a simplified representation and the concepts disclosed may be implemented in a metrology tool such as illustrated in FIG. 5 (also a simplified representation), for example.

An Illumination source SO, which may be an extended and/or multi-wavelength source, provides source illumination SI (e.g., via a multimode fiber MF). An optical system, e.g., represented here by lens L1, L2 and objective lens OL comprises a spatial filter or mask SF which is located in a pupil plane (Fourier plane) of the objective lens OL (or access is provided to this pupil plane for filtering). The optical system projects and focuses the filtered source illumination SI_{F} onto a target T on substrate S. As such a configurable illumination profile is provided such that the illumination pupil NA and position is defined by the filter SF. The diffracted radiation +1, −1 is guided by detection mirrors DM and lenses L3 to cameras/detectors DET (which may comprise one camera per diffracted order or a single camera or any other arrangement). As such, the detection pupil NA and position is defined by the area and position of detection mirrors DM.

In such an arrangement it may be that the detection mirrors and therefore detection pupil have a fixed size (NA) and position (as this is more practical physically). As such, it is proposed that the illumination pupil profile is configurable according to a particular target pitch (or strictly speaking and relevantly when illumination wavelength can be varied) wavelength-to-pitch ratio λ/P. The configurability of the illumination profile is such that the diffracted radiation (e.g., the +1 and −1 diffracted orders) are aligned with and substantially captured by the detection mirrors (e.g., one order per mirror); i.e., the position of +1 and −1 diffraction orders correspond and align with the detection pupils defined by the detection mirrors in pupil space.

In an embodiment, the overlapping/alignment of the +1 and −1 orders may be such that the whole of one of the orders overlaps one of the detection pupils defined by one or more, or two or more, separated detection regions (e.g., and are captured by the detection mirrors or other detection optical elements). In other embodiments, it may be at least 95%, at least 90%, at least 80% or at least 70% of the +1 and −1 orders overlap or fills the detection pupils defined by one or more, or two or more, separated detection regions (e.g., and are captured by the detection mirrors). In other arrangements, the relevant range is >=1% or >=10%. Assuming that the objective NA is 1, and an almost full open illumination profile is used (see FIG. 7(c)), 1% would correspond to a detection NA of approximately 0.10 [sine-angle]. Of particular relevance is that each of the detection regions is largely filled with the corresponding diffraction order (assuming an infinitely large target, so that the diffraction order forms a Dirac delta function in angular space, i.e. in the detection pupil space). This is similar to a summation over the Kohler illuminator in the equation above. It is desirable that all angles which can propagate are present. As angular space is limited to 1 [sine-angle] (i.e. an angle of 90 degrees) it is not possible to sum from −∞ to +∞, which would be ideal from a mathematical (spatial coherence) point of view.

As such, the method may provide for configuring an illumination aperture profile and/or orientation of the periodic structure based on wavelength/pitch combination such that radiation of at least a pair of complementary diffraction orders fills at least 80%, 85%, 90% or 95% the one or more separated detection regions. In an embodiment, this configuring may be such that radiation of at least a pair of complementary diffraction orders fills at least 100% the one or more separated detection regions.

It should be appreciated that a detection aperture profile and an illumination aperture profile are not necessarily created as physical apertures in the illumination pupil plane and the detection pupil plane respectively. The apertures may also be provided at other locations such that, when these apertures are propagated to the illumination pupil plane and the detection pupil plane, they respectively provide said detection aperture profile and said illumination aperture profile.

Each of the separate illumination regions may correspond to a respective one of said one or more detection regions. Each illumination region may be the same size or larger than its corresponding detection region; e.g., it may be that each illumination region is no more than 30% larger than its corresponding detection region. The single illumination region may comprise the available Fourier space other than the Fourier space used for the detection aperture profile and a margin between the illumination aperture profile and detection aperture profile.

The configurability of the illumination pupil profile can be achieved by selection of a particular spatial filter SF as appropriate. Filters may be manually inserted or mounted to a filter wheel for example. Other filtering options include providing a spatial light modulator SLM or digital micromirror device DMD in place of spatial filter SF, or even providing a spatially configurable light source for which its illumination profile can be directly configured. Any such method or any other method for obtaining and/or configuring a desired illumination profile may be used. The illumination aperture profile may comprise one or more illumination regions in Fourier space; e.g., two illumination regions for illuminating the periodic structure in two substantially different angular directions (e.g., two opposing directions) or four illumination regions for illuminating the periodic structure in two substantially different angular directions (e.g., two opposing directions) per target direction.

FIG. 7(a) illustrates a configuration where the detection pupil DP comprises four detection pupil regions DPR (e.g., as defined by four detection mirrors), which may be configured for measurement of the positive and negative diffraction order information for an X-target and Y-target simultaneously. As such the illumination pupil IP comprises four illumination regions ILR to illuminate the target in two opposing (angular) directions per X and Y orientation, and is configured according to the λ/P ratio such that the resultant four first diffraction orders (i.e., +1, −1 per direction, one order captured per illumination region ILR) are each coincident in k-space (also referred to as Fourier space or angular space) with a respective detection pupil region DPR and are therefore captured by a respective detection mirror. As is known, the illumination pupil regions should not overlap with the detection pupil regions in pupil space (i.e., the pupil is divided into exclusive illumination regions and detection regions, although some space may be neither). In an alternative embodiment illustrated in FIG. 7(b), the detection pupil DP has only two detection pupil regions DPR (e.g., two detection mirrors), which has the benefit of allowing for an increased detection NA, which reduces optical cross talk. As such, the illumination profile also has two illumination regions ILR to illuminate the target in two opposing (angular) directions. However, this would mean separate measurement in X and Y.

By way of a specific example, detection NA and the illumination NA may each comprise (e.g., in the example of FIG. 7(a)): 4×NA=0.18 to 0.23. For example, it may be that the detection NA and illumination NA each comprises 4×NA=0.21. Note that in each case, the illumination NAs may be equal to, or (e.g., slightly) larger than the detection NAs. In the FIG. 7(b) example, the detection NA may be e.g., 2×NA=0.23 to 0.27 (e.g., 2×NA=0.25), with a correspondingly larger illumination NA (e.g., which may be larger still, for example 2×NA=0.3). The illumination NA may be such that it overfills the detection NA for the +1, −1 detection orders. Overfilled in this context means that, for a target of infinite size, the diffraction order forms a Dirac delta pulse in the detection pupil plane. In practice, of course, targets must have finite size (e.g. 10 μm×10 μm), so the energy of the diffraction orders spreads out in pupil space. Because of this, increasing the illuminator to have a larger NA than the detection NA may have advantages in that it may help the image formation to become closer to the incoherent extreme. In this respect, note the equations for the two conditions/assumptions under which monochromatic image formation may be assumed to be spatially incoherent described above; i.e., in which the spatial mutual coherence function collapses to a Dirac delta function allowing the image formation to be computed without the need of phase information of the target.

FIG. 7(c) illustrates a further illumination arrangement which obviates the need for a configurable/programmable illuminator. In this embodiment, the illumination region ILR comprises the majority of the available k-space; e.g., all space except the detection pupil regions DPR and a margin M therebetween to avoid optical cross talk from the specular reflection (the zeroth order) of the target and/or surrounding structures. To better illustrate this margin, the Figure shows the illumination pupil and detection pupil overlaid IP+DP. In this specific example this margin has a width that equals 0.08 sine-angle, but may be, for example in a range of 0.05 to 0.12, 0.05 to 0.1 or 0.07 to 0.09. This filled illumination profile may have an NA larger than 0.9, or larger than 0.92 for example. This filled illumination profile may be used with the single direction detection pupil (two detection pupil regions) as illustrated in FIG. 7(b).

Such a configuration for which both the illumination NA and detections NA(s) are fixed in size and position while still having optimized illumination for different λ/P ratios, enables a smaller sensor volume, mass and cost of goods. This is important in case of using multiples of such sensors in parallel to increase measurement speed and/or wafer sampling density (i.e., to measure all/more wafers from a lot and/or more metrology targets per wafer).

Having the illumination NA equal or slightly larger than the detection NA can be shown to be sufficient from a practical point of view for the resulting imaging formation to be close to a spatial incoherent imaging formation; e.g., up to the point where an incoherent imaging model can be used computationally to accurately compute/predict the detected camera image. For example, a relevant related discussion can be found in section 7.2 and equation 7.2-61 of the book “Statistical Optics” by J. Goodman (ISBN 1119009456, 9781119009450), which is incorporated herein by reference. Being able to compute/predict the detected camera image in this manner, allows correction for detection optics aberrations via a deconvolution (e.g., Wiener like), which has the benefit of being cheap to compute. In this manner, the full vectorial problem may be split into two scalar problems. Should the aberrations be such that there are zeros in the MTF (Modulation Transfer Function), then a regularization (such as an L1-Total-Variation regularization) may be used to cope with these zeros. Such regularization is described in the aforementioned EP3480554.

For an incoherent sensor the Modulation Transfer Function (MTF) is sloped, which means that the signal-to-noise ratio (S/N ratio) of the measured information depends on the spatial frequencies which make up the target. To maximize the S/N ratio of the resulting overlay (and/or focus) inference, it is preferable not to overly magnify a spatial frequency component with a poor S/N. Therefore the proposed deconvolution operation should not make the effective MTF flat again, as that will result in a suboptimal overlay S/N ratio. The optimal balancing of the S/N ratio and the deconvolution gain (for each spatial frequency component) may result in a Wiener filter (as that does exactly that); and hence a “Wiener” like deconvolution.

Once captured, the camera image may be processed to infer the parameter of interest, e.g., overlay. Some processing operations performed on the image may include, for example, one or more of: edge detection, intensity estimation, periodic fit (if present in image). All of these operations can be (partially) written as a convolution operation (or a subsequent concatenation of multiple convolutions), e.g., region-of-interest kernel to weigh pixels for intensity estimation. The correction-kernel can be combined with all of these operations. Such an approach also makes it possible for the aberration correction operation to be made field position dependent. This way we can not only correct for field aberrations but also for pupil aberrations.

An example for flow of operations may be as follows, for a clean image I_{clean} and a raw measurement I_{raw}:

I_{clean}−I_{raw}*K

where K denotes the correction-kernel and * denotes the convolution operator. Where the clean and raw images are processed with a region of interest kernel (ROI kernel) R, then:

I_{clean}*R=I_{raw}*(K*R)

The convolution of the correction kernel (K) and the kernel(s) for further mathematical operations, e.g. ROI kernel R, can be calculated outside of the critical measurement path, e.g. at the start of a measurement job. It is also generic for all measurements so needs to be done only once for each mathematical operation. This approach is likely to be much more time-efficient then convoluting every acquired image with the correction-kernel.

In an embodiment, the correction convolution kernel may be combined with a convolutional neural network. For example, the evaluation (or functionality of) the convolutions (e.g., aberration correction, PSF reshaping and ROI selection convolutions) may be implemented using a convolutional neural network, comprising one or many layers. This means that one convolution, having a large footprint kernel, may be broken up into multiple convolutions, with smaller foot sized kernels. In this way, the field dependence of the aberrations can be implemented/covered by a neural network.

An additional possibility is to include (a form of) Wavefront Coding, to enlarge (for example) the useable focus range and/or to optimize the performance for one or more other aspects. This encompasses the deliberate introduction (of designed) aberrations in the sensor optics which can be corrected for by the computational aberration correction. This reduces the sensitivity for focus variations, and hence effectively increases the useable focus range. For example, the following reference article comprise more details and is incorporated herein by reference: Dowski Jr, Edward R., and Kenneth S. Kubala. “Modeling of wavefront-coded imaging systems.” In Visual Information Processing XI, vol. 4736, pp. 116-126. International Society for Optics and Photonics, 2002.

An additional possibility may comprise reshaping the (near) incoherent point spread function (PSF) shape by means of an apodization (which could be implemented in hardware, software or a hybrid thereof). An aberrated sensor results in a certain aberrated PSF. By means of the aberration correction, the PSF can be reshaped to that of an ideal/un-aberrated sensor. Additionally the optical cross talk may be reduced further by suppressing the sidelobes of the resulting PSF by means of applying an apodization. By way of specific example, a computational apodization may be applied, such that the resulting PSF approximates the shape of the (radial) Hanning windowing function.

A further image correction technique, e.g., for aberration correction, may be based on residual error. There are several ways to calibrate this error, for example:
A portion of the residual error could be determined by measuring a target under 0 and 180 degrees rotation. This captures the imbalance of the optics, but does not fully capture effects like crosstalk.
The residual error for the field-dependent component can be captured by imaging the target under different XY shifts.
The crosstalk error may be captured by measuring test targets with different surroundings.
   Such residual error calibrations can be determined on a limited set of targets to reduce the impact on the measurement time.

For some diffraction based overlay techniques, a target may comprise different pitches in each of its layers. In such as case, the detection NA should be large enough so that one illumination ray/position enables the contribution of both pitches to be detected/captured (there should be coherent interference between the two pitches at detector/camera level).

It is further proposed to include a (e.g., programmable) rotation of the wafer around the optical axis of the sensor (or at least rotation of the target around the optical axis of the sensor). This can be used to increase/maximize the illumination and/or detection NAs and/or to increase the λ/P ratio which can be supported (by releasing further available k-space). Alternatively or in addition, such a rotation capability can be used to further suppress crosstalk from neighboring structures, as it will result in different location of the four (or two) illumination pupils with respect to one of the detection pupils.

In such an embodiment, therefore, it is proposed to use an illumination and detection pupil geometry optimized in combination with a wafer rotation, wherein one or both of the illumination geometry (e.g., as already described) and the wafer rotation depends on the λ/P ratio.

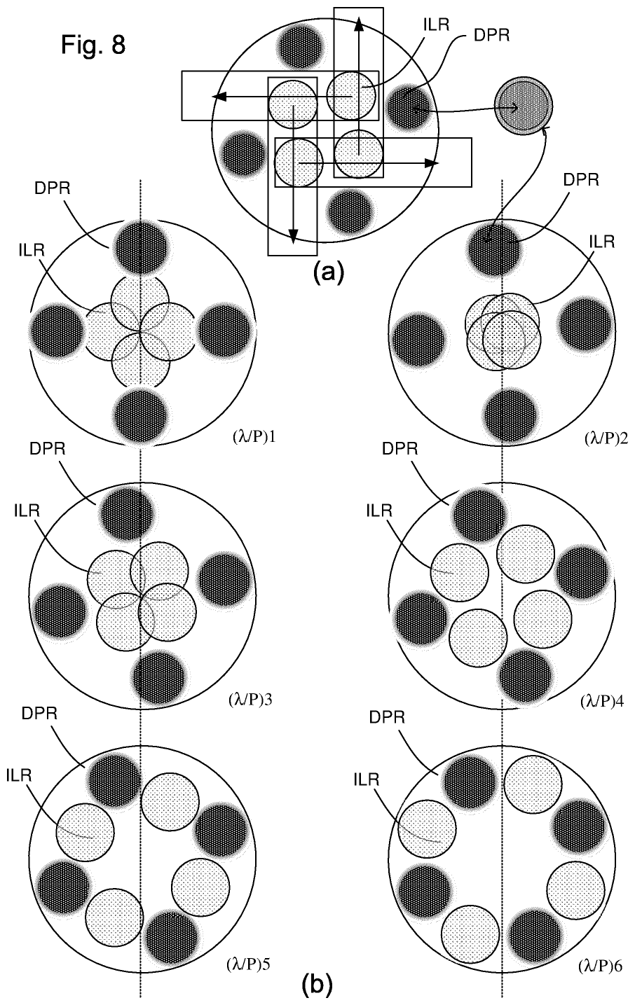

FIG. 8 shows an example of how such a wafer rotation may be used to increase detection (and illumination) NA and/or increase the range of usable λ/P ratios. FIG. 8(a) shows the arrangement without wafer rotation (i.e., it is the illumination and detection profiles of FIG. 7(a) overlaid). Note that the principles described in this section apply equally to any of the illumination and detection profiles of FIG. 7 (e.g., FIG. 7(b) or 7(c)) or any other arrangement within the scope of the disclosure. Without wafer rotation, for a fixed detection position DPR, the illumination positions ILR move along the arrows for an increasing λ/P ratio. This means that the detection and illumination NAs cannot be bigger than illustrated (as shown by the boxes) without significantly limiting the λ/P ratios which can be used otherwise the illumination and detection NAs overlap. In particular a number of intermediate ratios (e.g., corresponding to an intermediate portion of each path indicated by the arrows where each the illumination position ILR is close to a nearest detection region DPR) would be unavailable.

FIG. 8(b) shows six successive illumination profiles for respectively increasing λ/P ratios ((λ/P)1−(λ/P)6), and where the illumination profile optimization includes wafer rotation around the optical axis (note that it looks as if the sensor is rotated instead of the wafer in the drawings). It can be seen that the illumination and detection NAs (for the same given overall NA) is larger in FIG. 8(b), with a size comparison shown at the top of the Figure, while illumination and detection remains separate throughout the range of λ/P ratios. The rotation might only be employed for some λ/P ratios, e.g., to increase range for a given NA/detection profile.

It should also be appreciated that this concept of rotating the wafer according to λ/P ratio, taking into account the periodic pitches of the surrounding structures (e.g., to weaken the contribution of these surrounding structures to the parameter of interest, such as intensity asymmetry, overlay, focus, etc.), so as to optimize illumination profile and/or λ/P ratio range, can be employed on a metrology device independently of any other of the concepts disclosed herein, and for many different illumination and detection profiles and arrangements from those indicated.

In an embodiment, the rotation may be performed to optimize the margin M between the illumination and the detection pupils in a large illuminator embodiment such as that illustrated in FIG. 7(c); e.g., to reduce the leakage of specular reflected light which carries no information but contributes to the photon shot noise.

Other options for maximizing detection NA and/or the allowable range of λ/P ratios may comprise:
Rotate the wafer around its (local) normal.
Rotate the sensor around its optical central axis.
Rotate the target (periodic pattern) direction on the wafer.
Split the x-target and y-target measurement over two separate sensors.
Split the +1st and −1st diffraction order measurement over two separate sensors.
Division of the JP ratio range over two or more sensors, by means of splitting the wavelength range.
Division of the λ/P ratio range over two or more sensors, by means of splitting the pitch range.
Use of a solid/liquid immersion lens to increase the available k-space.
Any hybrid/permutation/combination of the above (including a split over more than two separate sensors).

As has been described, many of the above embodiments use separate illumination and detection pupils for each of the complementary pairs of diffraction orders for the X and Y targets. It may be that the optimal illumination conditions, for example the polarization conditions, are different for the X and Y targets. By way of specific example, X targets may require horizontal polarized light, while Y targets may require vertical polarized light. It is typical for a metrology device (such as illustrated in FIG. 5) to have the same setting during a single acquisition (e.g., for X and Y). Alternatively, to obtain optimal conditions, multiple (e.g., two) acquisitions may be made. This leads to degradation in speed.

Arrangements will now be described which enable measurement of the X and Y targets in parallel (and simultaneously in two directions) with different illumination conditions for different sets of these targets, more specifically for the X targets with respect to the Y targets. In an example, different illumination conditions may comprise differing in one or more of: polarization state, wavelength, intensity and on-duration (i.e., corresponding to integration time on the detector). In this manner, a two times shorter acquisition time for the same measurement quality is possible.

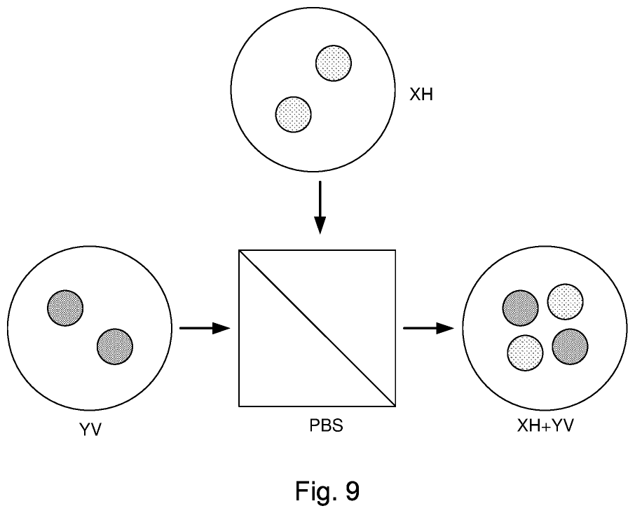

FIG. 9 illustrates a possible implementation for enabling separate polarization settings for X and Y. It shows an X illumination pupil having horizontal polarization XH and a Y illumination pupil having vertical polarization YV. These pupils are combined using a suitable optical element such as a polarizing beamsplitter PBS to obtain the combined illumination pupil XH+YV, which can then be used for measurement. The arrangement illustrated can be adapted simply for when the varied illumination condition is something other than polarization. As such the polarizing beamsplitter PBS may be replaced by another suitable beam combining element for combining illumination pupils of different wavelengths or differing on-durations. Such an arrangement is applicable where the illumination paths are different for X and Y illumination; there are many different ways to provide such different illumination paths, as will be apparent to the skilled person.

In an alternative arrangement, e.g., where the pupils are programmable, polarizers (or other elements depending on the illumination condition) may be placed in the path of each respective pupil. A programmable pupil may be implemented, for example, by modular illumination in comprising an embedded programmable digital micromirror device or similar device. Any suitable optical element(s) which changes illumination condition may be provided in the pupil plane of the tool to act on separate regions of the pupil plane.

In many of the embodiments described herein, the illumination is configured to achieve overfill of the detection NA (separated detection regions in pupil space). Overfill of the separated detection regions means that the diffraction illumination of the desired diffraction orders (e.g., +1. −1 pair of complementary orders from a target in one or two orientations) fills 100% of the pupil space (Fourier space) defined by the separated detection regions.

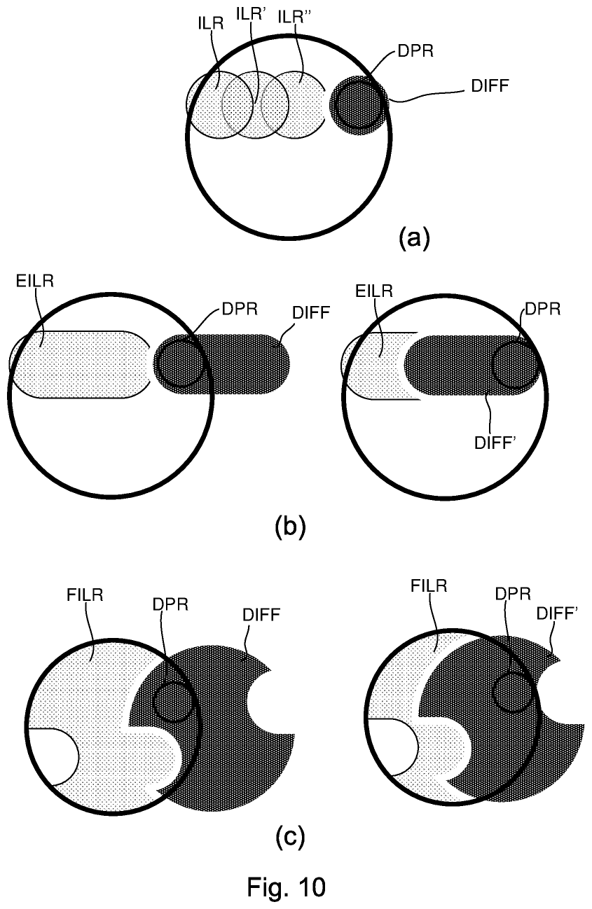

FIG. 10 illustrates three proposed methods for achieving such overfilled detection NA. In each case only one separated detection region DPR is shown, although there may be two or four in more common configurations. FIG. 10(a) shows a fully programmable arrangement, where an illumination region ILR, ILR′, ILR″ is moved to maintain the diffracted radiation DIFF in the same spot over the detection region DPR for different λ/P combinations (each illumination region ILR, ILR′, ILR″ corresponds to a different λ/P combination). In this manner the detection region DPR is maintained overfilled by the diffracted radiation DIFF. Control of the illumination profile can be achieved by any of the methods already disclosed herein (e.g., spatial filters, SLM, DMD, or spatially configurable light source).

FIGS. 10(b) and 10(c) illustrate preconfigured illumination regions which cover a range of different λ/P combinations. In FIG. 10(b) an elongated illumination region EILR is used (e.g., fixed) which covers different λ/P combinations defining a range extending from a first combination corresponding to a first extreme in the left Figure and to a second combination corresponding to a second extreme in the right Figure. Within this range the diffracted radiation DIFF, DIFF;′ always overfills the detection region DPR. FIG. 10(c) shows a similar arrangement but using a full illumination profile FILR which covers the entire Fourier space other than detection region DPR and a safety margin (a space in the full illumination profile FILR is provided for a second detection region). In FIGS. 10(a) and 10(b) corresponding illumination regions are required for another diffraction order, this is not the case for the full illumination profile FILR of FIG. 10(c).

In a (e.g., dark-field) scatterometer metrology device such as illustrated in FIG. 5, it is known to illuminate an overlay target (e.g., a micro-diffraction based overlay μDBO target) using a quartered illumination mask defining an illumination NA comprising two diagonally opposed quarters. The other two diagonally opposed quarters are used for detection and define the detection NA. The scattered radiation is split up into +1, −1 and (optionally) zeroth diffraction orders using a 4-part wedge. Such an arrangement enables simultaneous imaging of the +1, −1 and zeroth orders. In the detected image, the X- and Y-pads lie adjacent to each other. If aberrations are present, there will be XY crosstalk between these pads, which will negatively affect the overlay retrieval result.

Instead of such an arrangement, a number of specific Fourier plane arrangements for simultaneous spatially incoherent (or partially incoherent) imaging of multiple diffraction orders will be described. Each if these may be used in embodiments disclosed herein (i.e., in arrangements where diffracted radiation of at least a pair of complementary diffraction orders is captured within the detection aperture and fills at least 80% of the one or more separated detection regions).

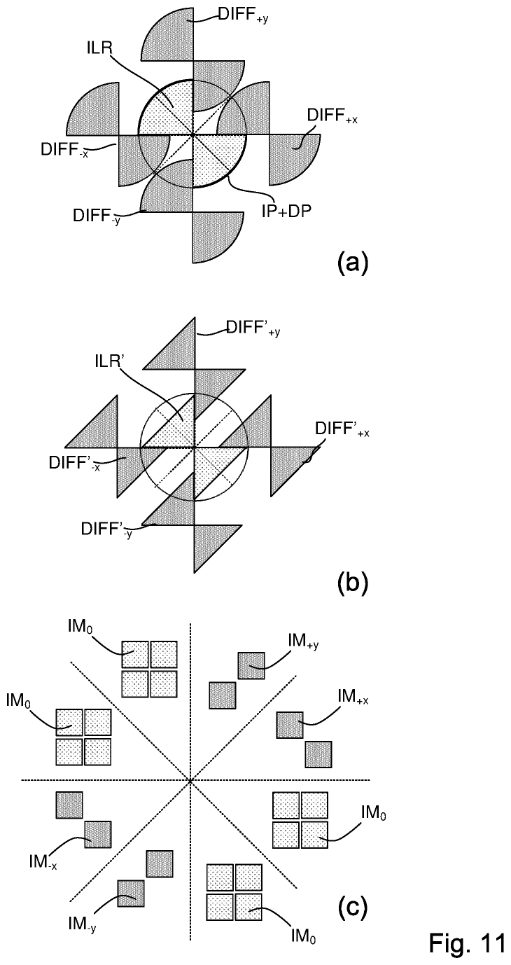

FIG. 11 illustrates a first proposed arrangement, which uses an optical element comprising an 8-part wedge in place of the 4-part wedge such that the X-pads and Y-pads are imaged separately.

The 8-part wedge may be located at the detection pupil plane and comprise an optical element having 8 parts that all have a wedge shaped cross-section (in a plane perpendicular to and through the center of the pupil plane) thereby refracting light in the respective parts of the pupil plane towards different locations at the image/detector plane.

It may be that fewer than 8 sections are required for the desired functionality. For example, a 45 degrees rotated (with respect to the orientation presently used) 4 part wedge may be sufficient to separate the +/−X/Y orders. Two additional parts may be provided to separate and capture the 0^{th} orders, for e.g., dose correction, or monitoring the lithographic processes which define the target.

Therefore, this embodiment may use an optical element comprising at least four wedges (or mirrors or other optical elements) which separate the different parts/areas (in particular the +/−X/Y orders) of the detection aperture profile.

In FIG. 11(a), the overlaid illumination pupil and detection pupil IP+DP is shown, divided into 8 segments (dotted lines). The illumination may comprise a quartered illumination profile ILR as with a 4 wedge mask. As can be seen, each diffraction order DIFF₊ₓ, DIFF₋ₓ, DIFF_{+y}, DIFF₋ₓ, coincides with a respective dedicated wedge or wedge part. FIG. 11(b) shows that, depending on the λ/P ratio of the pads, the illumination profile ILR′ may need to be truncated to (for example) an hourglass-shaped profile, so that diffraction orders DIFF′₊ₓ, DIFF′₋ₓ, DIFF′_{+y}, DIFF′₋ₓ, remain separated by the 8-part wedge.

FIG. 11(c) shows the resulting image at the image/detector plane. Images for the respective different orders IM₊ₓ, IM₋ₓ, IM_{+y}, IM₋ₓ, IM₀ are all at separate locations at this image plane. Therefore, using such a scheme, the usage of the detection NA space is maximized (i.e., maximizing imaging resolution), under the constraint that the X- and Y-diffraction orders remain separated (i.e. X- and Y-pads are imaged separately).

Because the X- and Y-pad diffraction orders go through different parts of the detection pupil, they are affected by different parts of the aberration function. In the current 4-part wedge configuration, it is not possible to apply aberration correction to the X- and Y-pads separately (the assumed problem is that there is XY-crosstalk due to aberrations, so it is not possible to spatially separate diffraction from the pads, and apply the aberration corrections separately). In the 8-part wedge setup, it is possible to apply aberration correction separately to the X- and Y-pads to reduce blurring and XX-crosstalk and YY-crosstalk. In order to apply computational image correction effectively, it is assumed that the image formation can be approximated as fully incoherent. In that case, image formation is described by a simple convolution, and image correction can be achieved by a simple deconvolution. Full incoherence can be (approximately) achieved using any of the methods already described and/or by illuminating the sample from all angles with mutually incoherent plane waves, i.e., the illumination pupil is filled entirely with mutually incoherent point sources. If the detection pupil is overfilled, it makes no difference whether the illumination pupil was completely filled (i.e., full incoherence) or partially coherent (i.e. partial coherence).

It should be appreciated that the arrangement shown in FIG. 11 is a specific arrangement for separating the diffraction orders, which may be generalized into any arrangement where the detection is split into 8 parts such that four parts capture a respective diffraction order of +1, −1 orders for each of two target directions and such that the other 4 parts may be used to capture the zeroth order diffraction. The parts can have any shape. A rotation symmetric layout has advantages for optical and mechanical manufacturing, but is not necessary. The illumination profile may be configured with respect to the detection NA to ensure there is no crosstalk between detected X- and Y-diffraction orders for as large as possible wavelength/pitch-range. This can be achieved by any of the methods already described. The detection and illumination masks can be (co-)optimized for incoherence, wavelength/pitch-range, cDBO pitch difference, illumination efficiency, number of available aperture slots, etc.

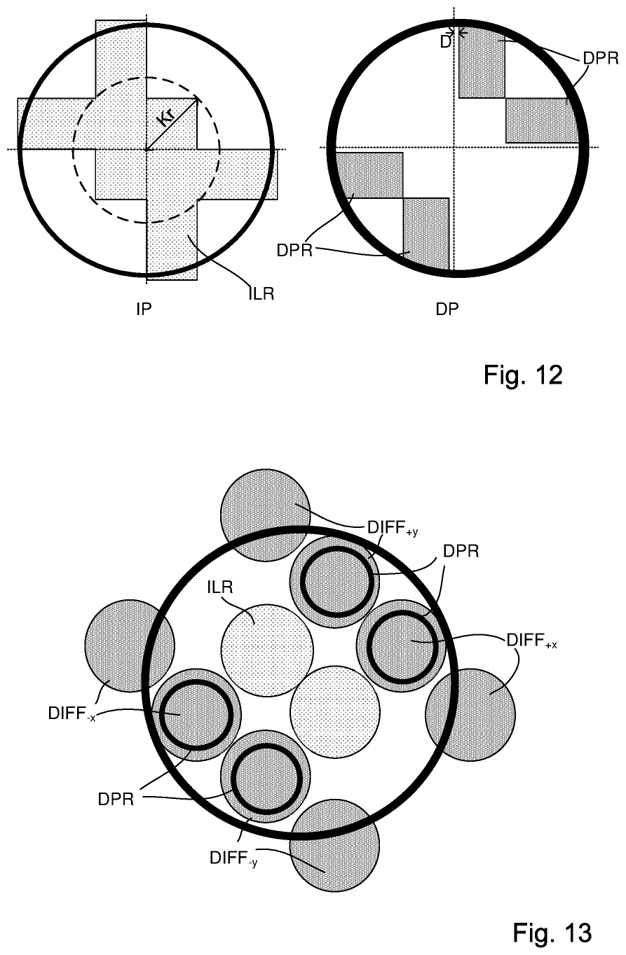

FIG. 12 illustrates another embodiment which enables a high level of incoherence by overfilling the detection over a very large wavelength/pitch-range (to enable good performance on computational image correction) while supporting a continuous DBO (cDBO) application by being able to detect two different pitches with limited loss of illumination efficiency. Briefly, cDBO metrology may comprise measuring a cDBO target which comprises a type A target or a pair of type A targets (e.g., per direction) having a grating with first pitch p₁ on top of grating with second pitch p₂ and a type B target or pair of type B targets for which these gratings are swapped such that a second pitch p₂ grating is on top of a first pitch p₁ grating. In this manner, and in contrast to a μDBO target arrangement the target bias changes continuously along each target. The overlay signal is encoded in the Moiré patterns from (e.g., dark field) images.

In the example illustrated in FIG. 12, the illumination and detection masks are designed around two parameters:
Kr: XY limits for a main portion of the illumination region ILR (NA radius or central radial numerical aperture dimension). This can be chosen relatively freely, in this case Kr=0.4 (sin(alpha) units);
D: safety distance for detection regions DPR. A typical value may be between 0.03 and 0.15, or between 0.04 and 0.1, e.g., 0.05 (sin(alpha) units).
   Note that the detection pupil DP only shows first order detection areas, but the corresponding area (with a safety distance removed) of the illumination region ILR (or a subset of it) can be used for detection of the zeroth order.

FIG. 13 shows a further Fourier plane arrangement where the diffracted radiation DIFF₊ₓ, DIFF₋ₓ, DIFF_{+y}, DIFF₋ₓ from target structures overfills a respective detection region DPR but none of the other apertures. The Figure also shows a corresponding illumination profile ILR.

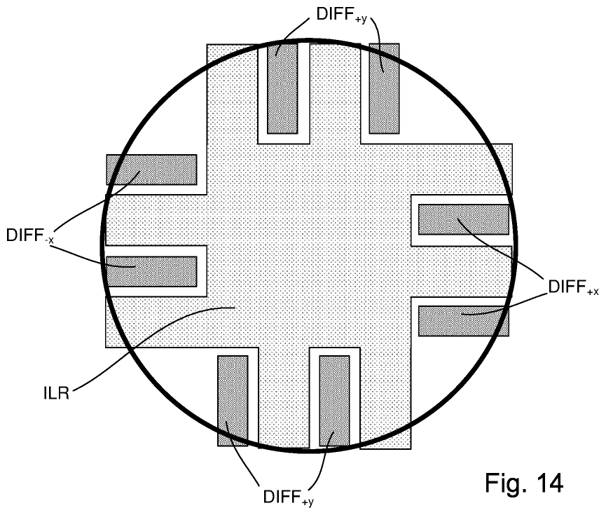

FIG. 14 shows a yet further Fourier plane arrangement where the diffracted radiation DIFF₊ₓ, DIFF₋ₓ, DIFF_{+y}, DIFF₋ₓ from target structures are each captured twice in two separate (e.g., overfilled) detection regions per order. Also shown is a corresponding illumination profile ILR. This arrangement enables correction for low order sensor artifacts (e.g., coma and/or astigmatism). Such an arrangement is also compatible with cDBO.

In all of the above arrangements, an optical element or wedge arrangement (e.g., having separate wedges for each diffraction order such as a multipart e.g., 4, 6 or 8-part wedge) can be used to separate the diffraction order images on the camera.

In many of the above arrangements, where separate detection regions separately capture a respective order, it can be appreciated that for each detection region the imaging is incoherent and that all scattered radiation will have been subject to the same aberrations. These aberrations can be corrected according to the following equation, where I is the captured image, |E|² is the object intensity and PSF is the Point Spread Function due to NA and aberrations:

I=|E|²⊗|PSF|²

It can be shown that deconvolution assuming incoherent imaging can be used to sufficiently correct for an image 10 μm out of focus (e.g., 5λ Z4 aberration) to obtain a good overlay value, which would not be possible using conventional imaging.

In the above, the illumination aperture profile and/or orientation of the periodic structure for a measurement is configured based on a detection aperture profile and the

$$\frac{λ}{p}$$

ratio. To cover sufficient high

$$\frac{λ}{p}$$

values (e.g., at least up to 1.3) the detection pupil apertures should be located at a high NA.

In an alternative embodiment it is proposed to provide for programmable or configurable detection aperture profiles such that, for a lower

$$\frac{λ}{p}$$

ratio, the centers of the detection apertures can be set at a lower NA. This has a number of additional advantages:
The lens aberrations are typically lower at lower NA;
For thicker stacks it is preferred to use a smaller pitch for overlay targets, use a small illumination aperture and maintain the illumination beam and 1st order detected beam close to the normal of the target to minimize parallax and distortion. This is enabled by a programmable detection aperture.
The impact of pupil aberrations can be suppressed if the imaging is operated close to the so-called Littrow conditions, where illumination and 1st order have the same angle of incidence; this is enabled by a programmable detection aperture.

For example, the illumination pupil profile (illumination aperture profile) and the detection pupil profile (illumination aperture profile) may both be programmable or configurable. A desirable implementation may comprise means to set each of the centers of the illumination and detection apertures at, or close to,

$$\frac{1}{2} \frac{λ}{p}$$

from the axis perpendicular to the grating pitch direction, to achieve, or at least approximate, the Littrow conditions;

There are a number of methods for implementation a configurable detection aperture profile which achieve these desirable features. A first proposal may comprise applying programmable shifts of the illumination and detection apertures in the pupil profiles. Such a method may use one or more optical elements to translate, or shift, the trajectories of both of the illumination and detection beams in the pupil plane.

In an embodiment the center location of the illumination pupil aperture is at, or close to, the same distance to the relevant axis as the center location of the detection pupil aperture, where the relevant axis is orthogonal to the direction of the pitch of the targets.

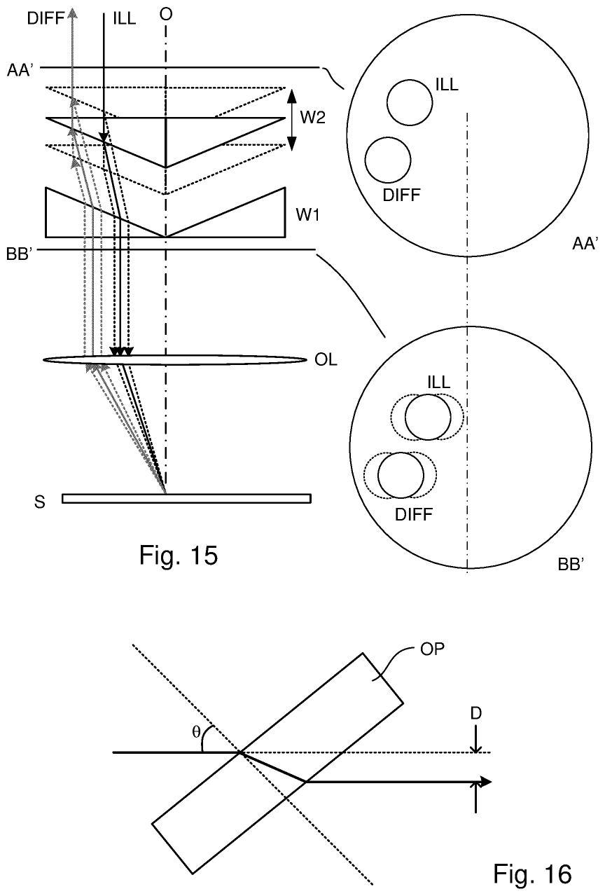

FIG. 15 is a simplified schematic diagram of such an arrangement. The arrangement is based on a pair of prisms, or optical wedge elements or wedges W1, W2 located at the pupil plane. The wedge elements may be oriented in opposite directions such that together they shift the illumination and detection beams in the pupil plane without substantially changing their direction (i.e., such that there is no change of directions between the beams input and output of the optical system defined by the pair of wedges, the change of direction imposed by a first of said wedges W1 being cancelled by an opposite change in direction imposed by the second of said wedges W2). The Figure also shows objective lens OL and substrate S. The initial illumination is defined by a fixed pupil (as shown in plane AA′). However the optical wedges W1, W2 are configurable to simultaneously vary the illumination and detection pupil apertures. In the embodiment shown, the optical wedges W1, W2 are configurable via a configurable or variable distance between the opposite planes AA′, BB′, by moving one or both of the wedges W1, W2 in a direction along the beam. The Figure shows the wedges (or more specifically, wedge W2) in three positions (a central position shown with solid lines, and two positions either side shown with dotted lines. Also shown are the illumination and 1st order diffracted radiation paths corresponding to each of these positions (again the paths are dotted for the paths corresponding to the dotted wedge W2 positions).

The prisms W1, W2 simultaneously translate the illumination and 1st order diffracted radiation in the pupil plane by the same magnitude in the same direction, depending on their separation, as shown in plane BB′. As shown, the complementary illumination and diffracted light can be shifted in the opposite direction, as required, using opposite oriented wedges on the other side of the optical axis O.

As an alternative to the wedges having a variable separation distance, other arrangements may comprise wedges having a programmable or configurable opening angle. For example one or both wedges W1, W2 may be a tunable wedge based on liquid lens technology (e.g., liquid lens optical elements).

Ideally, the illumination and detection apertures have the same distance to the optical y-axis (for x-gratings). However, this is not required, as shown in the figure.

The mechanical movement of the prisms should be fast, to allow short switching times. It can be demonstrated that an order of magnitude of 1 ms switching should be feasible.

As an alternative to prisms with configurable separation distance or shape, the optical elements may comprise optical plates (e.g., tiltable or rotatable optical plates), one at each side of the y-axis, to shift the beams FIG. 16 illustrates schematically such a rotating optical plate OP, where the displacement D is dependent on the incident angle θ.

In an embodiment, a beam separating/combining unit may be provided to the prism based arrangement just described. The beam separating/combining unit may be provided just above the prisms (or in another pupil plane). This unit separates the illumination beams from the diffracted beam.

Such a beam separating/combining unit may comprise, for example, a pair of small mirrors placed in each illumination path, to direct the illumination but not the diffracted radiation (e.g., the mirror may act as a partial pupil stop) such that the diffracted radiation only proceeds towards a detector. Alternatively the mirrors may be placed to direct the diffracted radiation but not the illumination.

A pair of beam splitters (e.g., small beam splitting cubes) can be used in a similar manner, positioned in the path of both illumination and diffracted radiation, but configured to deflect only one of these. The beam splitters can be combined with wedges for directing the normal and complementary diffraction orders to different parts of the detector, where the image on the detector is relayed with a single lens (e.g., similar to the four part wedge arrangement already described).

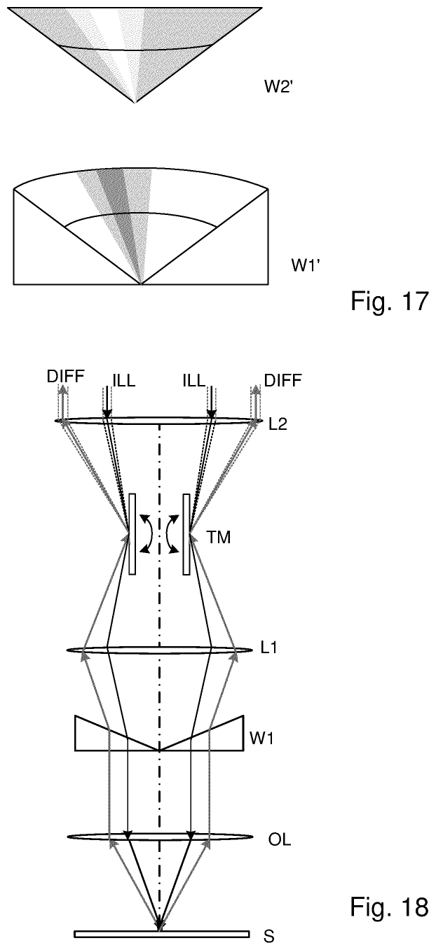

The arrangement described above enables detection in only one grating direction (e.g., X or Y). FIG. 17 illustrates a further embodiment, where a cone shaped (or axicon) wedge W2′, with corresponding dished wedge W1′ (the latter shown in cross-section) may be used to make the illumination and detection aperture profiles in both X and Y directions configurable. These wedges may replace wedges W1, W2 of FIG. 15. As alternative, parallel acquisition in X and Y may be achieved using 4 quadrant wedges instead of two halves shown in FIG. 15, albeit at the cost of a lower λ/pitch range which can be supported. Consecutive detection in X and Y can be achieved by rotation of the wedge unit in between the X and Y measurements.

Another alternative to program/configure the illumination and detection pupil is to use a zoom lens (instead of the axicon and dished lens arrangement) to create a magnified or demagnified image of the pupil in an (intermediate) pupil plane.

FIG. 18 illustrates a further embodiment comprising mirrors TM having a tunable or variable angle (e.g., galvo scan mirrors) in a (intermediate) field plane. Varying the tilt of the mirrors YM in the field plane results in a corresponding translation in the pupil plane. The Figure also shows objective lens OL, substrate S and lens system L1, L2. The two halves of the pupil are separated, e.g. using wedges W1 in a first pupil plane. In the field plane above these wedges, each half of the pupil plane will correspond to a displaced image (similar to the wedges presently used in the detection branch of some metrology tools, as has been described). In this plane, tiltable mirrors TM are used to change the angular direction of the illumination ILL and diffraction DIFF beams, which in turn corresponds to a shift or displacement in the subsequent pupil plan. Note that the mirrors TM can be put under any nominal angle around the other axis, tilting the remaining optics out of the plane. This may help to achieve a larger tilt range This idea can be extended easily to include both X and Y gratings. Such a mirror based embodiment may be used to achieve very short switching times of below 0.5 ms.

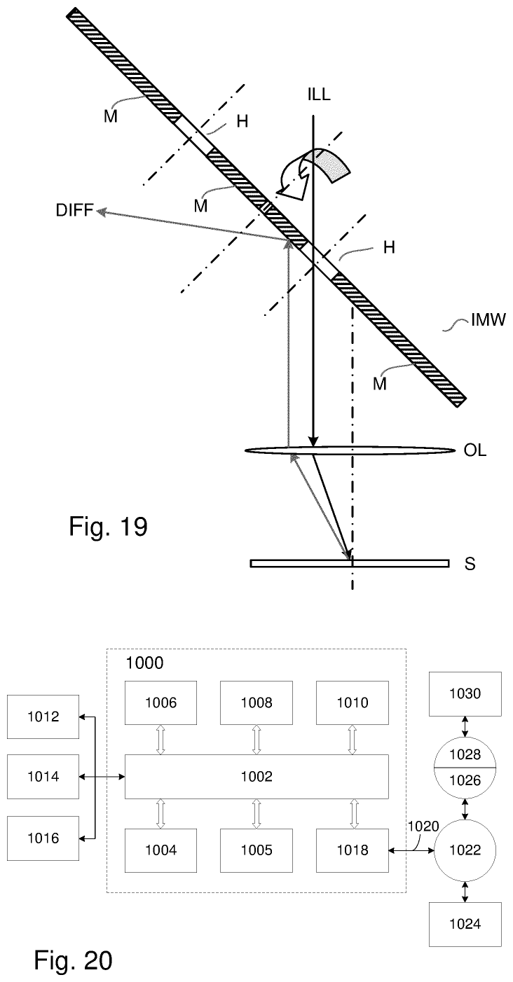

FIG. 19 illustrates a further embodiment which utilizes a switchable configuration of the illumination and detection pupil apertures, rather than a continuously programmable configuration. In this embodiment, an imaging mode element or imaging mode wheel IMW is placed in or around the pupil plane of the system, and is positioned under an angle so as to deflect the diffracted radiation DIFF away from of the direction of the objective lens OL. The imaging mode wheel IMW may comprise reflective regions and transmissive regions, e.g., tilted mirrors M and holes H. In the drawing, two positions of the wheel are shown, each with a different location of the holes H and mirrors M in the pupil plane, where the holes define the illumination aperture profile and the mirrors M define the detection aperture profile or vice versa.

The wheel IMW may comprise a number of rotation positions, each rotation position corresponding to one λ/pitch ratio. For each rotation position, the location and tilt of the mirrors M and/or holes H will be different and such that they can be moved into a desired location to define desired illumination and detection aperture profiles for a given λ/pitch ratio.

By providing appropriate different tilts of the mirror M sections, the function of the imaging mode wheel IMW also provides the function of the previously described wedges some current systems (i.e., to separate the normal and complementary orders in the image plane). The illumination may be provided in a manner similar to that described in relation to FIG. 5 using an illumination mode selector. However, this results in lost light, since the full NA must be illuminated, and a large portion subsequently blocked by the illumination aperture. To avoid this loss of light, this embodiment can be combined with tiltable mirrors in the field plane, as described in relation to FIG. 18, to couple the programmable pupil part to a fixed, small NA illumination beam, thus avoiding loss of light.

The described arrangements are just examples and skilled persons in the field of optical design will know how to implement differing illumination conditions for subsets of illumination regions in alternative ways.

Note that the arrangement described above show only an example of how such a system may be implemented, and different hardware setups are possible. It may even be that the illumination and the detection are not necessarily through the same lens, for example.

During a measurement acquisition, components of the metrology system vary with respect to the preferred or optimum measurement condition, e.g. XYZ positioning, illumination/detection aperture profile, central wavelength, bandwidth, intensity, etc. When this variation with respect to the optimum condition is known (e.g., via direct measurement or prediction), the acquired image can be corrected for this variation, e.g. via a deconvolution.

As throughput of a metrology system increases, more time is spend on settling of components after a (fast) move, e.g. wafer stage XY-move. For a measurement sequence, the metrology system is programmed for specific set-points at which acquisitions are taken. Each scanning component will have its own trajectory during this sequence. An optimization can be performed to co-optimize all scanning components and other system limitations. The correction for variation of components during acquisition, as described above, can then be used to correct for all the known variations.

Measurements can also be acquired before and after the ideal acquisition moment in time. These measurements will have lower quality due to worse measurement conditions, but can still be used to retrieve relevant information. Measurements can be weighted with a quality KPI based on the deviation from the optimum measurement conditions.

In all the above embodiment, the illumination may be a temporally modulated (e.g., with a modulation within the integration time of measuring one target). This modulation may help to increase the number of (spatially) incoherent modes, and hence suppress coherence. To implement such a modulation, a modulation element such as a fast rotating grounded glass plate may be implemented within in the illumination branch to provide a (temporal) summation of many speckle modes.

FIG. 20 is a block diagram that illustrates a computer system 1000 that may assist in implementing the methods and flows disclosed herein. Computer system 1000 includes a bus 1002 or other communication mechanism for communicating information, and a processor 1004 (or multiple processors 1004 and 1005) coupled with bus 1002 for processing information. Computer system 1000 also includes a main memory 1006, such as a random access memory (RAM) or other dynamic storage device, coupled to bus 1002 for storing information and instructions to be executed by processor 1004. Main memory 1006 also may be used for storing temporary variables or other intermediate information during execution of instructions to be executed by processor 1004. Computer system 1000 further includes a read only memory (ROM) 1008 or other static storage device coupled to bus 1002 for storing static information and instructions for processor 1004. A storage device 1010, such as a magnetic disk or optical disk, is provided and coupled to bus 1002 for storing information and instructions.

Computer system 1000 may be coupled via bus 1002 to a display 1012, such as a cathode ray tube (CRT) or flat panel or touch panel display for displaying information to a computer user. An input device 1014, including alphanumeric and other keys, is coupled to bus 1002 for communicating information and command selections to processor 1004. Another type of user input device is cursor control 1016, such as a mouse, a trackball, or cursor direction keys for communicating direction information and command selections to processor 1004 and for controlling cursor movement on display 1012. This input device typically has two degrees of freedom in two axes, a first axis (e.g., x) and a second axis (e.g., y), that allows the device to specify positions in a plane. A touch panel (screen) display may also be used as an input device.

One or more of the methods as described herein may be performed by computer system 1000 in response to processor 1004 executing one or more sequences of one or more instructions contained in main memory 1006. Such instructions may be read into main memory 1006 from another computer-readable medium, such as storage device 1010. Execution of the sequences of instructions contained in main memory 1006 causes processor 1004 to perform the process steps described herein. One or more processors in a multi-processing arrangement may also be employed to execute the sequences of instructions contained in main memory 1006. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor 1004 for execution. Such a medium may take many forms, including but not limited to, non-volatile media, volatile media, and transmission media. Non-volatile media include, for example, optical or magnetic disks, such as storage device 1010. Volatile media include dynamic memory, such as main memory 1006. Transmission media include coaxial cables, copper wire and fiber optics, including the wires that comprise bus 1002. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 1004 for execution. For example, the instructions may initially be borne on a magnetic disk of a remote computer. The remote computer can load the instructions into its dynamic memory and send the instructions over a telephone line using a modem. A modem local to computer system 1000 can receive the data on the telephone line and use an infrared transmitter to convert the data to an infrared signal. An infrared detector coupled to bus 1002 can receive the data carried in the infrared signal and place the data on bus 1002. Bus 1002 carries the data to main memory 1006, from which processor 1004 retrieves and executes the instructions. The instructions received by main memory 1006 may optionally be stored on storage device 1010 either before or after execution by processor 1004.

Computer system 1000 also preferably includes a communication interface 1018 coupled to bus 1002. Communication interface 1018 provides a two-way data communication coupling to a network link 1020 that is connected to a local network 1022. For example, communication interface 1018 may be an integrated services digital network (ISDN) card or a modem to provide a data communication connection to a corresponding type of telephone line. As another example, communication interface 1018 may be a local area network (LAN) card to provide a data communication connection to a compatible LAN. Wireless links may also be implemented. In any such implementation, communication interface 1018 sends and receives electrical, electromagnetic or optical signals that carry digital data streams representing various types of information.

Network link 1020 typically provides data communication through one or more networks to other data devices. For example, network link 1020 may provide a connection through local network 1022 to a host computer 1024 or to data equipment operated by an Internet Service Provider (ISP) 1026. ISP 1026 in turn provides data communication services through the worldwide packet data communication network, now commonly referred to as the “Internet” 1028. Local network 1022 and Internet 1028 both use electrical, electromagnetic or optical signals that carry digital data streams. The signals through the various networks and the signals on network link 1020 and through communication interface 1018, which carry the digital data to and from computer system 1000, are exemplary forms of carrier waves transporting the information.

Computer system 1000 may send messages and receive data, including program code, through the network(s), network link 1020, and communication interface 1018. In the Internet example, a server 1030 might transmit a requested code for an application program through Internet 1028, ISP 1026, local network 1022 and communication interface 1018. One such downloaded application may provide for one or more of the techniques described herein, for example. The received code may be executed by processor 1004 as it is received, and/or stored in storage device 1010, or other non-volatile storage for later execution. In this manner, computer system 1000 may obtain application code in the form of a carrier wave.

Further embodiments are disclosed in the subsequent list of numbered clauses:

1. A method of measuring a periodic structure on a substrate with illumination radiation having at least one wavelength, the periodic structure having at least one pitch, the method comprising:
configuring, based on a ratio of said pitch and said wavelength, one or more of:
   an illumination aperture profile comprising one or more illumination regions in Fourier space;
   an orientation of the periodic structure for a measurement; and
   a detection aperture profile comprising one or more separated detection regions in Fourier space;
   such that: i) diffracted radiation of at least a pair of complementary diffraction orders is captured within the detection aperture profile, and ii) said diffracted radiation fills at least 80% of the one or more separated detection regions; and
measuring the periodic structure while applying the configured one or more of illumination aperture profile, detection aperture profile and orientation of the periodic structure.
   2. A method as defined in clause 1, wherein the illumination aperture profile comprises said one or more illumination regions in Fourier space for illuminating the periodic structure from at least two substantially different (e.g., opposing) angular directions, and the detection aperture profile comprises at least two separated detection regions in Fourier space, for capturing a respective one of said pair of complementary diffraction orders.
   3. A method as defined in clause 2, wherein the illumination aperture profile comprises said one or more illumination regions in Fourier space, for illuminating the periodic structure from two groups of said two substantially different (e.g., opposing) angular directions for each of the two periodic orientations of sub-structures comprised within the periodic structure, and the detection aperture profile comprises four detection regions in Fourier space, for capturing a respective one of said pair of complementary diffraction orders for each of said periodic orientations.
   4. A method as defined in clause 2 or 3, wherein a separate illumination region of said one or more illumination regions each corresponds to a respective one of each detection region, and wherein each illumination region is the same size or larger than its corresponding detection region.
   5. A method as defined in clause 4, wherein each illumination region is no more than 10% larger, or optionally, no more than 20% larger, or optionally, no more than 30% larger than its corresponding detection region.
   6. A method as defined in clause 2 or 3, wherein said one or more illumination regions comprises only a single illumination region.
   7. A method as defined in clause 6, wherein the single illumination region comprises the available Fourier space other than the Fourier space used for the detection aperture profile and a margin between the illumination aperture profile and detection aperture profile.
   8. A method as defined in any of clauses 2 to 7, wherein each of said detection regions defines a numerical aperture no larger than 0.4
   9. A method as defined in any preceding clause, wherein said configuring an illumination aperture profile comprises spatial filtering the illumination radiation in a pupil plane or intermediate plane of an objective lens, or equivalent plane thereof, to impose said illumination profile.
   10. A method as defined in any preceding clause, comprising imposing different illumination conditions for at least two different said illumination regions and/or detection regions.
   11. A method as defined in any preceding clause, wherein said illumination radiation comprises multimode radiation; or temporal and/or spatial incoherent radiation or an approximation thereof.
   12. A method as defined in clause 11, comprising temporally modulating said illumination radiation with a modulation within the integration time of the measurement.
   13. A method as defined in clause 12 wherein, said modulation is implemented by rotating a grounded glass plate within the illumination radiation sufficiently fast so as to provide a temporal summation of many speckle modes.
   14. A method as defined in clause 11, 12 or 13, comprising correcting an image of the periodic structure obtained during the measurement.
   15. A method as defined in clause 14, wherein said correcting comprises correcting said image for aberrations in sensor optics used to perform the measurements.
   16. A method as defined in clause 15, wherein said correcting said image for aberrations is performed as an image position dependent correction.
   17. A method as defined clause 15 or 16, wherein said correcting comprises performing a convolution of a raw image and correction kernel, where the correction kernel is position dependent.
   18. A method as defined in clause 17, wherein said correcting further comprises a convolution for each of one or more image processing operations.
   19. A method as defined in clause 15, 16, 17 or 18, wherein said correcting is applied using a convolutional neural network.
   20. A method as defined any of clauses 15 to 19, wherein said method comprises correcting said image to reshape the point spread function for aberrations in the point spread function due to the sensor optics used to perform the measurements.
   21. A method as defined any of clauses 15 to 20, wherein said correcting comprises reducing crosstalk in the image by computational apodization or a similar shaping technique.
   22. A method as defined in any of clauses 15 to 21, further comprising correcting the image for any deviation from an optimum measurement condition.
   23. A method as defined in any of clauses 15 to 22, wherein said aberrations comprise deliberate wavefront modulating aberrations, and said method comprises correcting for the wavefront modulating aberrations so as to enlarge the useable focus range and/or depth of field of the sensor optics.
   24. A method as defined in any of clauses 14 to 23, wherein said correcting is based on a residual error determined by one or more of: performing a measuring a periodic structure under two opposing rotations to determine a residual error attributable to measurement optics, and imaging the periodic structure under different positional shifts in the substrate plane to capture the residual error for a field-dependent component.
   25. A method as defined in any preceding clause, wherein the illumination radiation comprises a wavelength band spanning multiple wavelengths, and said at least one wavelength comprises the central wavelength.
   26. A method as defined in any preceding clause, wherein said configuring an orientation of the periodic structure comprises rotating the periodic structure around the optical axis in dependence on said ratio of pitch(es) and wavelength.
   27. A method as defined in clause 26, wherein said rotating the periodic structure is performed by rotating the substrate round the optical axis or rotating at least a part of the sensor around the optical axis.
   28. A method as defined in clause 26 or 27, wherein said rotating the periodic structure is such that it enables an increased area of the detection aperture profile and/or illumination aperture profile; and/or measurability of increased range of said pitches and/or with an increased range of said wavelengths than without rotation and/or better suppression of crosstalk from surrounding structures.
   29. A method as defined in any preceding clause, wherein the illumination aperture profile comprises a plurality of illumination regions in Fourier space for illuminating the periodic structure from at least two substantially different (e.g. opposing) angular directions, and subsets of said illumination regions comprise different illumination conditions.
   30. A method as defined in clause 29, wherein the different illumination condition comprises one or more of: polarization state, intensity, wavelength and integration time.
   31. A method as defined in clause 29 or 30, wherein the plurality of illumination regions comprises two pairs of said illumination regions, each pair comprising said different illumination conditions.
   32. A method as defined in clause 31, comprising combining the two pairs of illumination regions using a beam combining device.
   33. A method as defined in clause 32, wherein the beam combining device is a polarizing beam splitter.
   34. A method as defined in clause 31, wherein one or more optical elements are placed in the path of one or both of each said pair of illumination regions in the Fourier space to provide said different illumination conditions.
   35. A method as defined in any preceding clause, wherein said diffracted radiation fills at least 80% of the one or more separated detection regions.
   36. A method as defined in any preceding clause, wherein diffracted radiation from each captured diffraction order is imaged separately in an image plane.
   37. A method as defined in any preceding clause, wherein diffracted radiation from each captured diffraction order is imaged twice.
   38. A method as defined in any preceding clause, comprising simultaneously configuring both of said illumination aperture profile and detection aperture profile.
   39. A method as defined in clause 38, wherein said simultaneously configuring step comprises varying one or more optical elements in the path of at least a pair of said diffracted beams of said diffracted radiation and at least a pair of illumination beams of said illumination radiation such that trajectories of said diffracted beams and said illumination beams are translated and/or shifted in said Fourier space.
   40. A method as defined in clause 39, wherein said one or more optical elements are such that together they shift said diffracted beams and said illumination beams in said Fourier space without substantially changing their direction.
   41. A method as defined in clause 39 or 40, wherein the one or more optical elements comprises a pair of optical wedge elements having similar configuration per pair of illumination and diffraction beams but oriented in opposite directions.
   42. A method as defined in clause 39 or 40, wherein the one or more optical elements comprises: an axicon or cone element and corresponding dished element; or a zoom lens arrangement operable to create a magnified or demagnified images of the Fourier space in an (intermediate) pupil plane.
   43. A method as defined in clause any of clauses 39 to 42, wherein said varying one or more optical elements comprises varying a separation distance between a pair of optical elements.
   44. A method as defined in any of clauses 39 to 42, wherein said varying one or more optical elements comprises varying an opening angle of the one or more optical elements, wherein said optical elements comprise liquid lens optical elements.
   45. A method as defined in clause 39 or 40, wherein said varying one or more optical elements comprises varying the angle of at least a pair of optical plates.
   46. A method as defined in any of clauses 39 to 45 wherein said one or more optical elements are comprised within a pupil plane.
   47. A method as defined in clause 39 or 40, wherein said varying one or more optical elements comprises varying the angle of at least a pair of optical mirrors in a field plane or intermediate field plane.
   48. A method as defined in any of clauses 39 to 47, comprising further optical elements for separating said illumination beams from said diffraction beams prior to detection of the diffracted beams.
   49. A method as defined in clause 38, wherein said varying one or more optical elements comprises positioning different configurations of reflective regions and transmissive regions in a pupil plane.
   50. A method as defined in clause 49, wherein said positioning different configurations of one or more reflective regions and one or more transmissive regions in a pupil plane comprises varying the orientation and/or position of an imaging mode element comprising said reflective regions and transmissive regions.
   51. A method as defined in any preceding clause, wherein configuring an illumination aperture profile comprises configuring a central radial aperture dimension which is to comprise only illumination radiation.
   52. A method as defined in clause 51, further comprising configuring a safety margin for each of said one or more separated detection regions with respect to said illumination aperture profile.
   53. A metrology device being operable to perform the method of any of clauses 1 to 52.
   54. A metrology device for measuring a periodic structure on a substrate, the metrology device comprising:
   a detection aperture profile comprising one or more separated detection regions in Fourier space; and
   an illumination aperture profile comprising one or more illumination regions in Fourier space;
   wherein one or more of: said detection aperture profile, said illumination aperture profile and a substrate orientation of a substrate comprising a periodic structure being measured is/are configurable based on a ratio of at least one pitch of the periodic structure and at least one wavelength of illumination radiation used to measure said periodic structure, such that:
   i) at least a pair of complementary diffraction orders are captured within the detection aperture profile, and
   ii) radiation of the pair of complementary diffraction orders fills at least 80% of the one or more separated detection regions.
   55. A metrology device as defined in clause 54, wherein the illumination aperture profile comprises said one or more illumination regions in Fourier space, for illuminating the periodic structure from at least two substantially different (e.g., opposing) angular directions, and the detection aperture profile comprises at least two separated detection regions in Fourier space, for capturing a respective one of said pair of complementary diffraction orders.
   56. A metrology device as defined in clause 54, wherein the illumination aperture profile comprises one or more illumination regions in Fourier space, for illuminating the periodic structure from two groups of said two substantially different (e.g., opposing) angular directions for each of the two periodic orientations of sub-structures comprised within the periodic structure, and the detection aperture profile comprises four separated detection regions in Fourier space, for capturing a respective one of said pair of complementary diffraction orders for each of said periodic orientations.
   57. A metrology device as defined in clause 55 or 56, comprising a separate said illumination region corresponding to a respective one of each detection region, and wherein each illumination region is the same size or larger than its corresponding detection region.
   58. A metrology device as defined in clause 57, wherein each illumination region is no more than 10% larger, or optionally, no more than 20% larger, or optionally, no more than 30% larger than its corresponding detection region.
   59. A metrology device as defined in clause 55 or 56, wherein said one or more illumination regions comprises a single illumination region.
   60. A metrology device as defined in clause 59, wherein the single illumination region comprises the available Fourier space outside that used for the detection aperture profile and a margin between the illumination aperture profile and detection aperture profile.
   61. A metrology device as defined in any of clauses 55 to 60, wherein each of said detection regions defines a numerical aperture no larger than 0.4.
   62. A metrology device as defined in any of clauses 55 to 61, comprising detection mirrors or other optical elements, each of which defines the position and aperture of a respective one of said detection regions.
   63. A metrology device as defined in any of clauses 54 to 62, comprising a spatial filter to impose said illumination aperture profile by filtering the illumination radiation in a pupil plane or intermediate plane of an objective lens, or equivalent plane thereof.
   64. A metrology device as defined in clause 63, wherein the spatial filter is physically replaceable depending on the ratio of pitch and wavelength.
   65. A metrology device as defined in clause 64, wherein a plurality of spatial filters are mounted on a filter wheel.
   66. A metrology device as defined in clause 63, wherein the spatial filter comprises a programmable spatial light modulator.
   67. A metrology device as defined in any of clauses 54 to 62, comprising an illumination source with a configurable illumination profile to impose said illumination aperture profile.
   68. A metrology device as defined in any of clauses 54 to 67, being operable to impose different illumination conditions for at least two different said illumination regions and/or detection regions.
   69. A metrology device as defined in any of clauses 54 to 68, wherein said illumination radiation comprises multimode radiation; or incoherent radiation or an approximation thereof.
   70. A metrology device as defined in clause 69, comprising a modulation element for temporally modulating said illumination radiation with a modulation within the integration time of the measurement.
   71. A metrology device as defined in clause 70, wherein said modulation element comprises a rotatable grounded glass plate.
   72. A metrology device as defined in any of clauses 54 to 71, comprising a processor configured to correct an image of the periodic structure obtained during the measurement.
   73. A metrology device as defined in clause 72, wherein said processor is operable to correct said image for aberrations in sensor optics used to perform the measurements.
   74. A metrology device as defined in clause 73, wherein said processor is operable to correct said image for aberrations as an image position dependent correction.
   75. A metrology device as defined in clause 73 or 74, wherein said processor is operable to perform said correction via a convolution of a raw image and correction kernel, where the correction kernel is position dependent.
   76. A metrology device as defined in clause 75, wherein said processor is operable to perform said correction as a convolution for each of one or more image processing operations.
   77. A metrology device as defined in any of clauses 73 to 76, wherein said processor is configured to said perform said correction using a convolutional neural network.
   78. A metrology device as defined in any of clauses 73 to 77, wherein said processor is further operable to correct said image to reshape the point spread function for aberrations in the point spread function due to the sensor optics used to perform the measurements.
   79. A metrology device as defined in any of clauses 73 to 78, wherein said processor is further operable further to correct the image for any deviation from an optimum measurement condition.
   80. A metrology device as defined any of clauses 73 to 79, wherein said aberrations comprise deliberate wavefront modulating aberrations, and said processor is further configured to correct for the wavefront modulating aberrations so as to enlarge the useable focus range and/or depth of field of the sensor.
   81. A metrology device as defined any of clauses 72 to 80, wherein said processor is operable to reduce crosstalk in the image by computational apodization or a similar shaping technique.
   82. A metrology device as defined any of clauses 72 to 81, operable to perform said correcting based on a residual error determined by one or more of: performing a measuring a periodic structure under two opposing rotations to determine a residual error attributable to measurement optics, and imaging the periodic structure under different positional shifts in the substrate plane to capture the residual error for a field-dependent component.
   83. A metrology device as defined in any of clauses 54 to 82, wherein the illumination radiation comprises a wavelength band spanning multiple wavelengths, and said at least one wavelength comprises the central wavelength.
   84. A metrology device as defined in any of clauses 54 to 83, comprising a substrate support for holding the substrate, the substrate support being rotatable around its optical axis, the metrology device being operable to configure the substrate orientation at least in part by rotating the substrate around the optical axis or rotating at least a part of the sensor around the optical axis in dependence on said ratio of pitch and wavelength.
   85. A metrology device as defined in clause 84, wherein said rotating the substrate is such that it enables an increased area of the detection aperture profile and/or illumination aperture profile; and/or measurability of increased range of said pitches and/or with an increased range of said wavelengths than without rotation.
   86. A metrology device as defined in any of clauses 54 to 85, comprising an illumination source for providing said illumination radiation.
   87. A metrology device as defined in any preceding clause, wherein the illumination aperture profile comprises a plurality of illumination regions in Fourier space for illuminating the periodic structure from at least two substantially opposing angular directions, and subsets of said illumination regions comprise different illumination conditions.
   88. A metrology device as defined in clause 87, wherein the different illumination condition comprises one or more of: polarization state, intensity, wavelength and integration time.
   89. A metrology device as defined in clause 87 or 88, wherein the plurality of illumination regions comprises two pairs of said illumination regions, each pair comprising said different illumination conditions.
   90. A metrology device as defined in clause 89, comprising a beam combining device operable to combine the two pairs of illumination regions.
   91. A metrology device as defined in clause 90, wherein the beam combining device is a polarizing beam splitter.
   92. A metrology device as defined in clause 89, comprising one or more optical elements in the path of one or both of each said pair of illumination regions in the Fourier space to provide said different illumination conditions.
   93. A metrology device as defined in any of clauses 54 to 92, wherein said diffracted radiation fills 100% of the one or more separated detection regions.
   94. A metrology device as defined in any of clauses 54 to 93, comprising an optical element operable such that diffracted radiation from each captured diffraction order is imaged separately in an image plane.
   95. A metrology device as defined in any of clauses 54 to 94, operable such that diffracted radiation from each captured diffraction order is imaged twice.
   96. A metrology device as defined in any of clauses 54 to 95, being arranged for simultaneous configuration of both of said illumination aperture profile and detection aperture profile.
   97. A metrology device as defined in clause 96, wherein said simultaneously comprising one or more optical elements in the path of at least a pair of said diffracted beams of said diffracted radiation and at least a pair of illumination beams of said illumination radiation, said one or more optical elements being variable such that trajectories of said diffracted beams and said illumination beams are translated and/or shifted in said Fourier space.
   98. A metrology device as defined in clause 97, wherein said one or more optical elements are such that together they shift said diffracted beams and said illumination beams in said Fourier space without substantially changing their direction.
   99. A metrology device as defined in clause 97 or 98, wherein the one or more optical elements comprises a pair of optical wedge elements having similar configuration per pair of illumination and diffraction beams but oriented in opposite directions.
   100. A metrology device as defined in clause 97 or 98, wherein the one or more optical elements comprises:
   an axicon or cone element and corresponding dished element; or
   a zoom lens arrangement operable to create a magnified or demagnified images of the Fourier space in an (intermediate) pupil plane.
   101. A metrology device as defined in clause any of clauses 97 to 100, wherein said one or more optical elements comprises a variable separation distance between a pair of optical elements, the variation of which simultaneously configures of both of said illumination aperture profile and detection aperture profile.
   102. A metrology device as defined in any of clauses 97 to 100, wherein said optical elements comprise liquid lens optical elements and at least one of the one or more optical elements comprises a variable opening angle, the variation of which simultaneously configures of both of said illumination aperture profile and detection aperture profile.
   103. A metrology device as defined in clause 97 or 98, wherein said one or more optical elements comprises at least a pair of optical plates, the variation of an angle of each of which simultaneously configures of both of said illumination aperture profile and detection aperture profile.
   104. A metrology device as defined in any of clauses 97 to 103 wherein said one or more optical elements are comprised within a pupil plane of the metrology device.
   105. A metrology device as defined in clause 97 or 98, wherein said one or more optical elements comprises at least a pair of optical mirrors in a field plane or intermediate field plane of the metrology device, the variation of an angle of each of which simultaneously configures of both of said illumination aperture profile and detection aperture profile.
   106. A metrology device as defined in any of clauses 97 to 105, comprising further optical elements for separating said illumination beams from said diffraction beams prior to detection of the diffracted beams.
   107. A metrology device as defined in clause 96, comprising an imaging mode element in a pupil plane of the metrology device, said imaging mode element comprising one or more reflective regions and one or more transmissive regions, the imaging mode element being arranged such that varying its orientation and/or position simultaneously configures of both of said illumination aperture profile and detection aperture profile.
   108. A metrology device as defined in any of clauses 54 to 107, wherein said illumination aperture profile is configurable to define a central radial numerical aperture dimension which is to comprise only illumination radiation.
   109. A metrology device as defined in clause 108, further comprising a configurable safety margin for each of said one or more separated detection regions with respect to said illumination aperture profile.
   110. A metrology device for measuring a periodic structure on a substrate and having at least one periodic pitch, with illumination radiation having at least one wavelength, the metrology device comprising: a substrate support for holding the substrate, the substrate support being rotatable around its optical axis, the metrology device being operable to optimize an illumination aperture profile by rotating the substrate around the optical axis in dependence on said ratio of pitch and wavelength.
   111. A metrology device as defined in clause 109, wherein said rotating the substrate is such that it enables an increased area of the detection aperture profile and/or illumination aperture profile; and/or measurability of increased range of said pitches and/or with an increased range of said wavelengths than without rotation.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of an inspection or metrology apparatus, embodiments of the invention may be used in other apparatus. Embodiments of the invention may form part of a mask inspection apparatus, a lithographic apparatus, or any apparatus that measures or processes an object such as a wafer (or other substrate) or mask (or other patterning device). The term “metrology apparatus” may also refer to an inspection apparatus or an inspection system. E.g. the inspection apparatus that comprises an embodiment of the invention may be used to detect defects of a substrate or defects of structures on a substrate. In such an embodiment, a characteristic of interest of the structure on the substrate may relate to defects in the structure, the absence of a specific part of the structure, or the presence of an unwanted structure on the substrate.

Although specific reference is made to “metrology apparatus/tool/system” or “inspection apparatus/tool/system”, these terms may refer to the same or similar types of tools, apparatuses or systems. E.g. the inspection or metrology apparatus that comprises an embodiment of the invention may be used to determine characteristics of structures on a substrate or on a wafer. E.g. the inspection apparatus or metrology apparatus that comprises an embodiment of the invention may be used to detect defects of a substrate or defects of structures on a substrate or on a wafer. In such an embodiment, a characteristic of interest of the structure on the substrate may relate to defects in the structure, the absence of a specific part of the structure, or the presence of an unwanted structure on the substrate or on the wafer.

Although specific reference may have been made above to the use of embodiments of the invention in the context of optical lithography, it will be appreciated that the invention, where the context allows, is not limited to optical lithography and may be used in other applications, for example imprint lithography.

While the targets or target structures (more generally structures on a substrate) described above are metrology target structures specifically designed and formed for the purposes of measurement, in other embodiments, properties of interest may be measured on one or more structures which are functional parts of devices formed on the substrate. Many devices have regular, grating-like structures. The terms structure, target grating and target structure as used herein do not require that the structure has been provided specifically for the measurement being performed. Further, pitch P of the metrology targets may be close to the resolution limit of the optical system of the scatterometer or may be smaller, but may be much larger than the dimension of typical product features made by lithographic process in the target portions C. In practice the lines and/or spaces of the overlay gratings within the target structures may be made to include smaller structures similar in dimension to the product features.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1-15. (canceled)

16. A method comprising:
configuring, based on a ratio of a pitch of a periodic structure on a substrate and a wavelength of illumination used to measure the periodic structure, one or more of:
an illumination aperture profile comprising one or more illumination regions in Fourier space;
an orientation of the periodic structure for a measurement; and
a detection aperture profile comprising one or more separated detection regions in Fourier space;
such that: i) diffracted radiation of at least a pair of complementary diffraction orders is captured within the detection aperture profile, and ii) the diffracted radiation fills at least 80% of the one or more separated detection regions; and
measuring the periodic structure while applying the configured one or more of illumination aperture profile, detection aperture profile and orientation of the periodic structure.

17. The method of claim 16, wherein:
the illumination aperture profile comprises the one or more illumination regions in Fourier space for illuminating the periodic structure from at least two substantially different angular directions; and/or
the two substantially different angular directions are two opposing directions.

18. The method of claim 17, wherein:
the illumination aperture profile comprises the one or more illumination regions in Fourier space, for illuminating the periodic structure in the two substantially different angular directions for each of two periodic orientations of sub-structures comprised within the periodic structure, and
the detection aperture profile comprises four detection regions in Fourier space, for capturing a respective one of the pair of complementary diffraction orders for each of the periodic orientations.

19. The method of claim 17, wherein:
a separate illumination region of the one or more illumination regions each corresponds to a respective one of each detection region, and
each illumination region is the same size or larger than its corresponding detection region; and/or
each illumination region is no more than 30% larger than its corresponding detection region.

20. The method of claim 17, wherein the one or more illumination regions comprises a single illumination region comprising the available Fourier space other than the Fourier space used for the detection aperture profile and a margin between the illumination aperture profile and detection aperture profile.

21. The method of claim 16, wherein the configuring an illumination aperture profile comprises spatial filtering the illumination radiation in a pupil plane or intermediate plane of an objective lens, or equivalent plane thereof, to impose the illumination profile.

22. The method of claim 16, wherein the illumination radiation comprises multimode radiation, temporal and/or spatial incoherent radiation, or an approximation thereof.

23. The method of claim 22, further comprising:
correcting an image of the periodic structure obtained during the measurement.

24. The method of claim 23, wherein the correcting comprises correcting the image for aberrations in sensor optics used to perform the measurements.

25. The method of claim 24, wherein the correcting for aberrations is performed as a field position dependent correction.

26. The method of claim 24, wherein the correcting comprises performing a convolution of a raw image and correction kernel, the correction kernel being position dependent.

27. The method of claim 24, wherein the method comprises correcting the image to reshape the point spread function for aberrations in the point spread function due to the sensor optics used to perform the measurements.

28. The method of claim 16, wherein the configuring an orientation of the periodic structure comprises rotating the periodic structure around the optical axis in dependence on the ratio of pitch(es) and wavelength.

29. The method of claim 16, further comprising:
simultaneously configuring both of the illumination aperture profile and detection aperture profile;
the configuring comprising varying one or more optical elements in the path of at least a pair of the diffracted beams of the diffracted radiation and at least a pair of illumination beams of the illumination radiation such that trajectories of the diffracted beams and the illumination beams are translated and/or shifted in the Fourier space.

30. A metrology device comprising:
a detection aperture profile comprising one or more separated detection regions in Fourier space; and
an illumination aperture profile comprising one or more illumination regions in Fourier space,
wherein one or more of:
the detection aperture profile, the illumination aperture profile and a substrate orientation of a substrate comprising a periodic structure being measured is/are configurable based on a ratio of at least one pitch of the periodic structure and at least one wavelength of illumination radiation used to measure the periodic structure, such that:
i) at least a pair of complementary diffraction orders are captured within the detection aperture profile, and
ii) radiation of the pair of complementary diffraction orders fills at least 80% of the one or more separated detection regions.
